(19) United States
(12) Patent Application Publication
(10) Pub. No.: US 2026/0006812 A1
(43) Pub. Date: Jan. 1, 2026

(54) SEMICONDUCTOR DEVICES WITH INSULATION FEATURES

(71) Applicant: Taiwan Semiconductor Manufacturing Company, Ltd., Hsinchu (TW)

(72) Inventor: Tzu-Ging Lin, Kaohsiung (TW)

(73) Assignee: Taiwan Semiconductor Manufacturing Company, Ltd., Hsinchu (TW)

(21) Appl. No.: 18/759,419

(22) Filed: Jun. 28, 2024

(51) Int. Cl. H01L 29/66; H01L 29/06; H01L 29/417; H01L 29/423; H01L 29/775; H01L 29/786

(52) U.S. Cl. CPC H10D 30/014; H10D 30/43; H10D 30/6729; H10D 30/6735; H10D 30/6757; H10D 62/121; H10D 64/017; H10D 64/018

(57) ABSTRACT

Semiconductor devices with insulation structures and methods of fabrication are provided. A method includes forming fins over a substrate; forming a gate over the fins, wherein a sidewall spacer is laterally adjacent to the gate; removing an upper portion of the sidewall spacer; forming a cavity by removing a selected segment of the gate and removing a selected fin located under the selected segment; and forming an insulation feature in the cavity.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart illustrating a method, in accordance with some embodiments.

FIG. 2 illustrates a top-down view of a semiconductor device, according to some embodiments.

FIGS. 3-8 are perspective schematic views of a device during successive stages of fabrication of the method of FIG. 1, in accordance with some embodiments.

FIG. 9 is an X-cut cross-sectional schematic view of the device at the stage of fabrication of FIG. 8.

FIGS. 10-15 are X-cut cross-sectional schematic views of the device during successive stages of fabrication of the method of FIG. 1, in accordance with some embodiments.

FIGS. 16-17 are Y-cut cross-sectional schematic views of the device during successive stages of fabrication of the method of FIG. 1, in accordance with some embodiments.

FIGS. 18 and 19, 20 and 21, 22 and 23, 24 and 25, 26 and 27, and 28 and 29 are each a pair of Y-cut and X-cut cross-sectional schematic views of the device, during successive stages of fabrication of the method of FIG. 1, in accordance with some embodiments.

FIGS. 30 and 31 are X-cut cross-sectional schematic views of the device, during successive stages of fabrication of the method of FIG. 1, in accordance with some embodiments.

FIG. 32 is a flow chart illustrating a method, in accordance with some embodiments.

FIGS. 33-38 are X-cut cross-sectional schematic views of the device, during successive stages of fabrication of the method of FIG. 32, in accordance with some embodiments.

FIG. 39 is a flow chart illustrating a method, in accordance with some embodiments.

FIGS. 40-42, 43-45, 46-48, 49-51, and 52-54 are perspective, X-cut, and Y-cut views of a device during successive fabrication stages, in accordance with some embodiments.

FIGS. 56-58, 59-61, 62-64 perspective, X-cut, and Y-cut views, and FIGS. 65-66 and 67-68 are X-cut and Y-cut views, of a device during successive fabrication stages, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material structure” is a structure that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a structure that is formed of a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of a tungsten structure and a structure formed of tungsten is a structure that is at least 50 wt. %, at least 60 wt. %, at least 75 wt. %, at least 90 wt. %, at least 95 wt. %, or at least 99 wt. % of tungsten.

For the sake of brevity, typical techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many typical processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Presented herein are embodiments of semiconductor devices and of methods for fabricating such devices. Methods described herein may be easily integrated into the current process flow. Further, methods described herein relate to the formation of an insulation structure, such as a Continuous Poly On Diffusion Edge (CPODE) structure or a Continuous Metal On Diffusion Edge (CMODE) structure, that divides a fin in two and/or a gate in two. In certain embodiments, a portion of a selected fin structure is removed and replaced with insulation material.

In embodiments herein, CMODE processing methods, i.e., formation of the insulation feature after metal gate formation, or CPODE processing methods, i.e., before metal gate formation, are provided. In certain embodiments, dielectric structures such cut-poly gate dielectric structures, cut-metal gate dielectric structures, or dummy fins form sidewalls of the cavity etched during the CMODE or CPODE process. Thus, the insulation feature is formed in contact with the dielectric structures. In other embodiments, the insulation features directly contacts remaining gate segments.

In certain embodiments, a sidewall spacer is located on the sidewall of the gate segment to be removed during the CPODE or CMODE process. In embodiments herein, the etch process used in the CPODE or CMODE process is tuned and controlled to remove at least an upper portion of the sidewall spacers, or all of the sidewall spacers, contacting the gate segment being removed. As a result, later processing for removing an adjacent ILD structure does not etch into or degrade the insulation feature or the insulation feature interface.

In other words, certain embodiments herein ensure that material similar to, or the same as, the material of the ILD structure, which would be etched during removal of the ILD structure, is not present at the upper surface adjacent to the insulation feature. When the ILD structure is silicon oxide, then embodiments remove silicon oxide from upper surface regions adjacent to where the insulation feature is formed. Further, certain embodiments may also provide for forming the insulation feature itself without a material similar to, or the same as, the material of the ILD structure, e.g., silicon oxide. In certain embodiments, the insulation feature may include a liner that is formed from a material that is similar to or the same as the material of the ILD structure, e.g., silicon oxide. In such embodiments, the thickness of the liner is minimized, such as having a thickness of no more than 4 nanometers, which may prevent or reduce etching degradation of the insulation feature at the interface.

Embodiments of the present disclosure offer advantages over the existing art, though it is understood that other embodiments may offer different advantages, not all advantages are necessarily discussed herein, and no particular advantage is required for all embodiments.

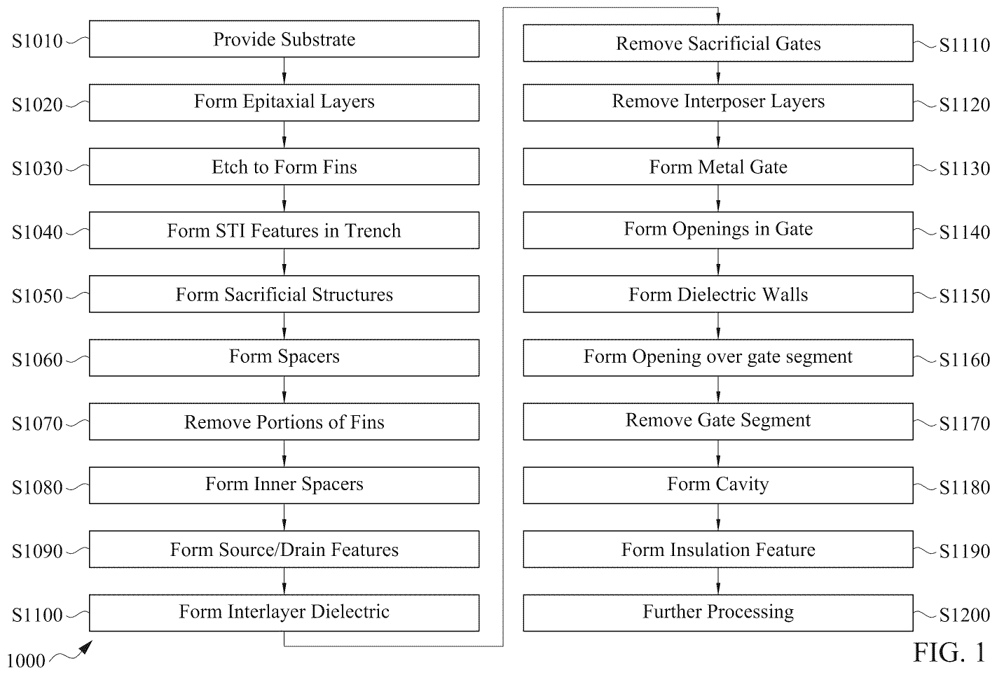

For purposes of the discussion that follows, FIG. 1 provides a flow chart for a method 1000 for fabricating a semiconductor device 100 during a semiconductor fabrication process.

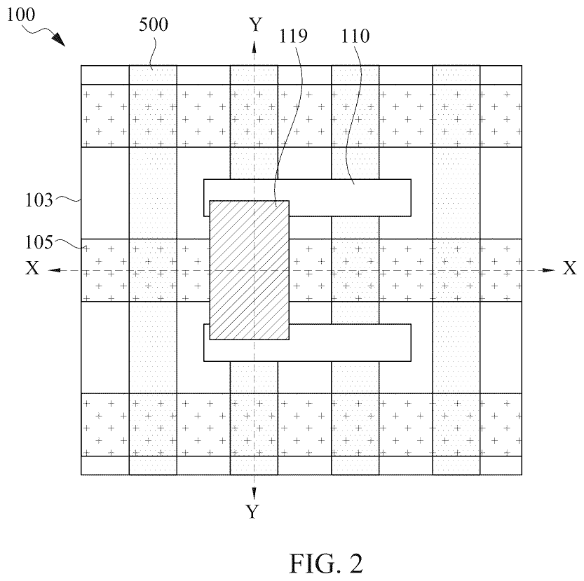

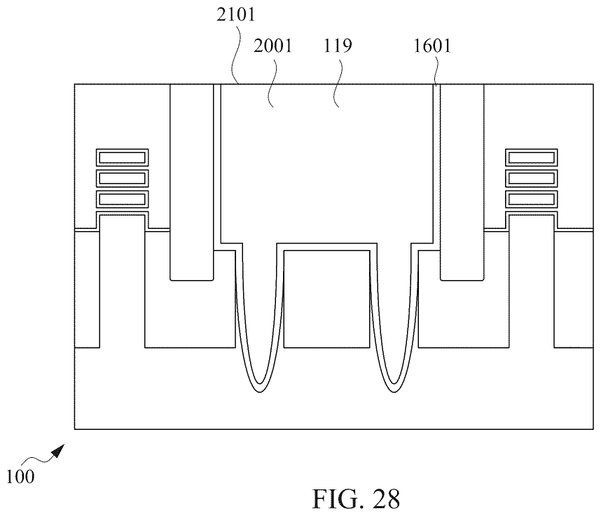

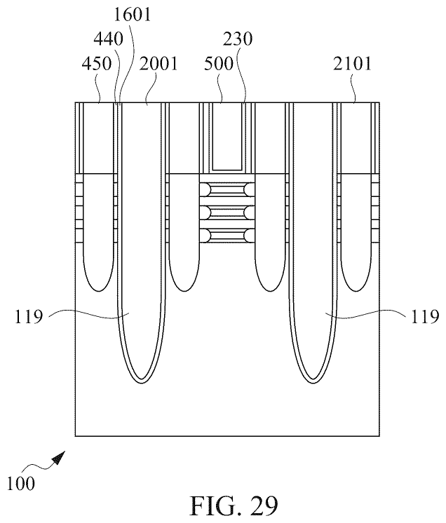

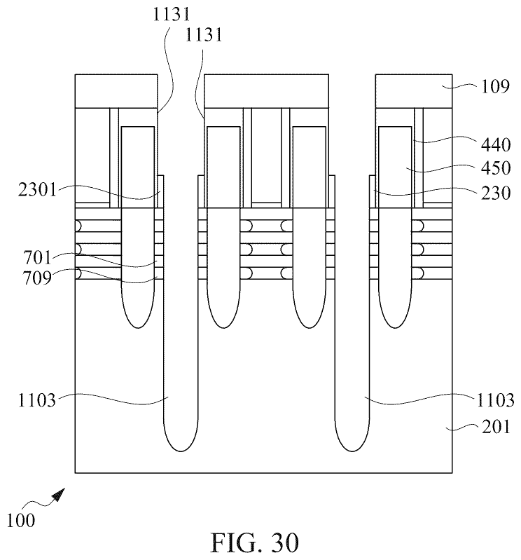

Method 1000 is described below with reference to FIGS. 2-29 which illustrate the semiconductor device 100 at various stages of fabrication according to method 1000. It is understood that method 1000 includes steps having features of a complementary metal-oxide-semiconductor (CMOS) technology process flow and thus, are only described briefly herein. Also, additional steps may be performed before, after, and/or during method 1000.

FIG. 2 illustrates a top-down view of an intermediate structure in forming a device 100, such as a gate-all-around (GAA) semiconductor device, according to some embodiments. In FIG. 2, the device 100 includes a multi-layer structure 103 comprising a plurality of nanosheets formed over a semiconductor substrate 201 (illustrated in the following figures), semiconductor structures 105, such as fins, formed in the multi-layer structure 103, and a plurality of gates 500 over the fins 105. FIG. 2 further illustrates a plurality of dielectric structures 110 separating two of the gates 500 and an insulation feature 119 dividing one of the fins 105 in two and intersecting a gate 500 and the dielectric structures 110.

It is noted that the device 100 may include any suitable number of fins 105 to form the desired semiconductor device 100. Furthermore, any suitable number of gates 500, insulation features 119, and dielectric structures 110 may be formed to form the desired semiconductor device 100.

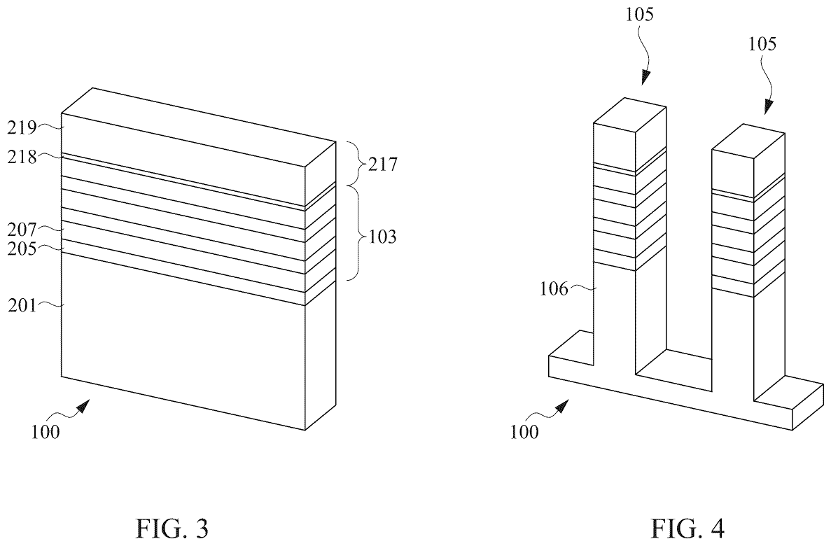

Referring now to FIGS. 1 and 3, a method 1000 for fabricating a semiconductor device 100 includes, at operation S1010, providing a substrate 201. In some embodiments, the substrate 201 may be a semiconductor substrate such as a silicon (Si) substrate. The substrate 201 may include various layers, including conductive or insulating layers formed on a semiconductor substrate. The substrate 201 may include various doping configurations depending on design requirements as is known in the art. For example, different doping profiles (e.g., p-well, n-well) may be formed on the substrate 201 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 201 includes a single crystalline semiconductor layer on at least its surface portion. The substrate 201 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 201 may include a compound semiconductor and/or an alloy semiconductor. In the illustrated embodiment, the substrate 201 is made of crystalline Si.

As shown in FIG. 3, at operation S1020, the method 1000 (FIG. 2) forms one or more epitaxial layers over the substrate 201. In some embodiments, an epitaxial stack 103 is formed over the substrate 201. The epitaxial stack 103 includes epitaxial layers 205 of a first composition interposed by epitaxial layers 207 of a second composition. The first and second composition may be different. Embodiments are possible including those that provide for a first composition and a second composition having different oxidation rates and/or etch selectivity. In an embodiment, the epitaxial layers 205 are silicon germanium (SiGe) and the epitaxial layers 207 are silicon. In embodiments wherein the epitaxial layer 205 includes SiGe and the epitaxial layer 207 includes silicon, the silicon oxidation rate is less than the SiGe oxidation rate. It is noted that three layers of epitaxial layers 205 and three layers of epitaxial layers 207 are illustrated in FIG. 3, which is for illustrative purposes only and not intended to be limiting beyond what is specifically recited in the claims. It can be appreciated that any number of epitaxial layers may be formed in the epitaxial stack 103; the number of layers depending on the desired number of channels regions for the GAA device 100. In some embodiments, the number of epitaxial layers 207 is between two and ten, such as six or seven.

In some embodiments, the epitaxial layer 205 has a thickness ranging from about five nanometers to about fifteen nanometers. The epitaxial layers 205 may be substantially uniform in thickness. In some embodiments, the epitaxial layer 207 has a thickness ranging from about five nanometers to about fifteen nanometers. In some embodiments, the epitaxial layers 207 of the stack are substantially uniform in thickness. As described in more detail below, the epitaxial layer 207 may serve as channel region(s) for a subsequently formed multi-gate device and has a thickness chosen based on device performance considerations. The epitaxial layer 205 may serve to define a gap between adjacent channel region(s) for a subsequently formed multi-gate device and has a thickness chosen based on device performance considerations.

By way of example, epitaxial growth of the epitaxial stack 103 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 207 include the same material as the substrate 201. In some embodiments, the epitaxially grown layers 205 and 207 include a different material than the substrate 201. As stated above, in at least some examples, the epitaxial layer 205 includes an epitaxially grown Si₁₋ₓGeₓ layer (wherein x is from about 10 to about 55%) and the epitaxial layer 207 includes an epitaxially grown silicon (Si) layer. In some embodiments, the epitaxial layer 205 includes epitaxially grown silicon oxide. Alternatively, in some embodiments, either of the epitaxial layers 205 and 207 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the epitaxial layers 205 and 207 may be chosen based on providing differing oxidation, etch selectivity properties. In various embodiments, the epitaxial layers 205 and 207 are substantially dopant-free (i.e., having an extrinsic dopant concentration from about 0 cm⁻³ to about 1×10¹⁷ cm⁻³), where for example, no intentional doping is performed during the epitaxial growth process. In some embodiments, the bottom layer and the top layer of the epitaxial stack 103 are SiGe layers (not shown). In alternative embodiments, the bottom layer of the epitaxial stack 103 is a Si layer and the top layer of the epitaxial stack 103 is a SiGe layer (not shown).

In some embodiments, the method includes forming a mask layer 217 over the epitaxial stack 103, as shown in FIG. 3. The mask layer 217 includes a first mask layer 218 and a second mask layer 219. An exemplary first mask layer 218 is a pad oxide layer made of a silicon oxide, which may be formed by a thermal oxidation. An exemplary second mask layer 219 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process.

As shown in FIG. 4, at operation S1030, the method 1000 (FIG. 2) patterns the epitaxial stack 103 to form semiconductor fins 105. For example, mask layer 217 may be patterned into a mask pattern by using patterning operations including photolithography and etching. Operation S1030 subsequently patterns the epitaxial stack 103 in an etching process, such as a dry etch (e.g., reactive ion etching), a wet etch, and/or other suitable process, through openings defined in the patterned mask layer 217. The stacked epitaxial layers 205 and 207 are thereby patterned into the fin 105. Further, the substrate 201 under the layers 205 and 207 may be patterned such that a mesa portion 106 of the substrate 201 forms a lower portion of the fin 105. While FIG. 4 illustrates the formation of two fins 105, any suitable number of the fins may be formed. Trenches are etched between adjacent fins 105.

In various embodiments, each fin 105 includes an upper portion of the interleaved epitaxial layers 205 and 207, and a bottom portion 106 that is formed from the etched substrate 201. Each fin 105 protrudes upwardly in the Z-direction from the substrate 201 and extends lengthwise in the Y-direction. Sidewalls of each fin 105 may be straight or inclined (not shown). In FIG. 4, additional fins would be spaced apart along the X-direction. The fins 105 may have a same width or different widths.

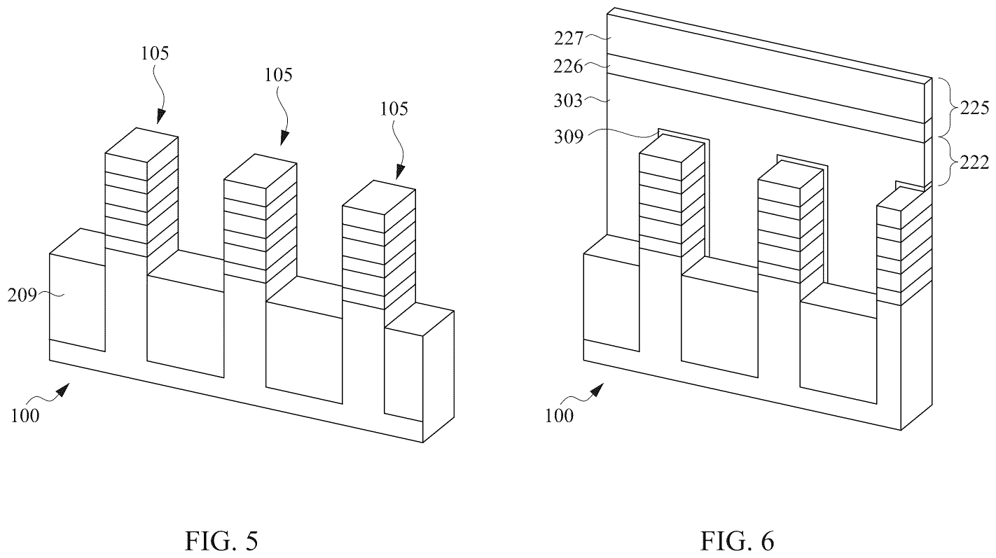

As shown in FIG. 5, at operation S1040, the method 1000 (FIG. 2) forms shallow trench isolation (STI) features (also denoted as STI features) 209 in trenches adjacent to each fin 105 with a dielectric layer. The STI features 209 may be formed by first filling the trenches around each fin 105 with a dielectric material layer to cover top surfaces and sidewalls of the fin 105 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask layer 217 are revealed, and the dielectric material layer is recessed to form the shallow trench isolation (STI) features (also denoted as STI features) 209, as shown in FIG. 5. In the illustrated embodiment, the STI features 209 are formed on the substrate 201. Any suitable etching technique may be used to recess the isolation features 209 including dry etching, wet etching, RIE, and/or other etching methods, and in an exemplary embodiment, an anisotropic dry etching is used to selectively remove the dielectric material of the isolation features 209 without etching the fin 105. The mask layer 217 (shown in FIG. 4) may also be removed before, during, and/or after the recessing of the isolation features 209. In some embodiments, the mask layer 217 is removed prior to the recessing of the isolation features 209. In some embodiments, the mask layer 217 is removed by an etchant used to recess the isolation features 209.

As shown in FIG. 6, at operation S1050, the method 1000 (FIG. 2) forms sacrificial (dummy) gate structures 222. FIG. 6 illustrates one half of a sacrificial gate structure 222. While FIG. 6 indicates the formation of one sacrificial gate structure 222, any suitable number of sacrificial gate structures may be formed. Each sacrificial gate structure 222 protrudes upwardly in the Z-direction from the substrate 201 and extends lengthwise in the X-direction. In FIG. 6, additional sacrificial gate structures would be spaced apart along the Y-direction.

The sacrificial gate structures 222 are formed over portions of the fin 105 which are to be channel regions. The sacrificial gate structures 222 may extend over a number of adjacent fins 105. The sacrificial gate structures 222 lie directly over and define the channel regions of the GAA devices to be formed. Each of the sacrificial gate structures 222 includes a sacrificial gate dielectric 309 and a sacrificial gate electrode 303 over the sacrificial gate dielectric 309.

The sacrificial gate structures 222 are formed by first blanket depositing a sacrificial gate dielectric layer over the fin(s) 105. A sacrificial gate electrode layer is then blanket deposited on the sacrificial gate dielectric layer and over the fin(s) 105. The sacrificial gate dielectric layer includes silicon oxide, silicon nitride, or a combination thereof. The thickness of the sacrificial gate electrode layer is in a range from about one hundred nanometers to about two hundred nanometers in some embodiments. The sacrificial gate electrode layer includes silicon such as polycrystalline silicon or amorphous silicon. The thickness of the sacrificial gate dielectric layer is in a range from about one nanometer to about five nanometers in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer 225 is formed over the sacrificial gate electrode layer. The mask layer 225 may include a mask layer 226 such as silicon oxide and a mask layer 227 such as silicon nitride. Subsequently, and as shown in FIG. 6, a patterning operation is performed on the mask layer 225, and the sacrificial gate electrode layers and the sacrificial gate dielectric layer are patterned into the sacrificial gate structures 222, including sacrificial gate dielectric layer 309 and sacrificial gate electrode 303.

After forming the sacrificial gate structures 222, each fin 105 is partially uncovered or exposed on opposite sides of the sacrificial gate structures 222, thereby defining source/drain (S/D) regions. In this disclosure, “source/drain region(s)” or “source/drain feature(s)” may refer to a source or a drain, individually or collectively dependent upon the context.

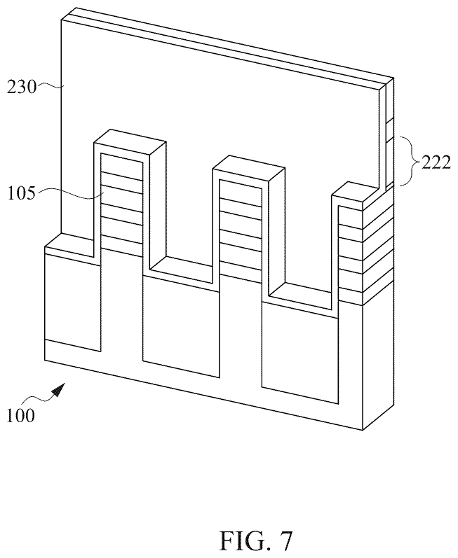

Referring now to FIG. 7, at operation S1060, the method 1000 (FIG. 2) forms sidewall spacers 230 on sidewalls of the sacrificial gate structures 222 and sidewalls of the fins 105 by depositing spacer materials, followed by an etching. The sidewall spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 may include multiple layers, such as a liner layer and a main spacer layer on the liner layer. In certain embodiments, the sidewall spacers 230 are silicon oxide.

By way of example, the sidewall spacers 230 may be formed by depositing spacer material including a liner material layer and a dielectric material layer over the sacrificial gate structure 222 using processes such as a subatmospheric CVD (SACVD) process, a flowable CVD process, an ALD process, a PVD process, or other suitable process respectively.

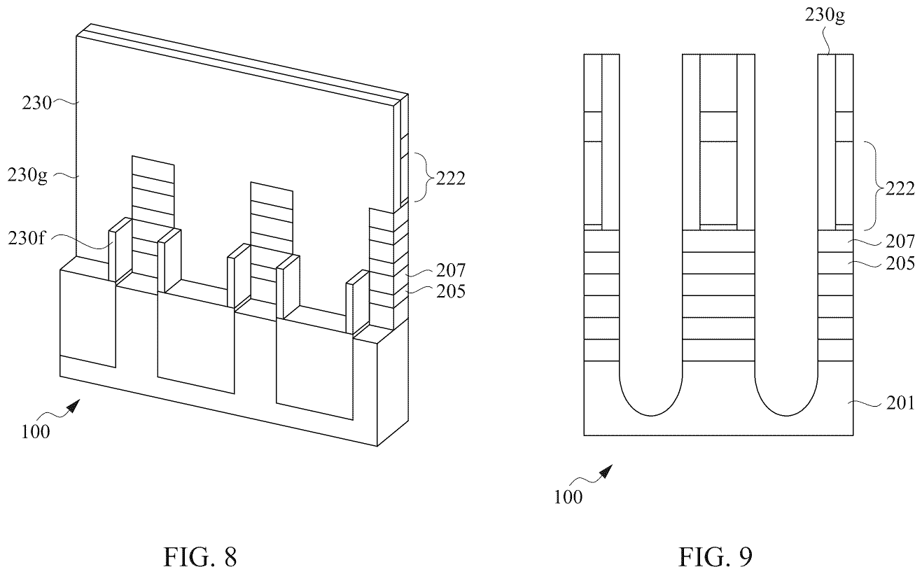

As shown in FIG. 8, the deposition of the liner material layer and the dielectric material layer are followed by, at operation S1070, etching-back (e.g., anisotropically) to expose, and remove, portions of the fins 105 adjacent to and not covered by the sacrificial gate structure 222 (e.g., source/drain regions). FIG. 9 is an X-cut cross-sectional view of the stage of fabrication of FIG. 8, along a single fin 105 and across a central sacrificial gate 222 located between illustrated portions of two adjacent sacrificial gates 222.

Cross-referencing FIGS. 8 and 9, the liner material layer and the dielectric material layer remains on the sidewalls of the sacrificial gate structure 222 as the gate sidewall spacers 230g, and on the sidewalls of the fins as the fin sidewall spacers 230f. In some embodiments, the etching-back process may include a wet etch process, a dry etch process, a multiple-step etch process, and/or a combination thereof. The spacers 230 may have a thickness ranging from about five nanometers to about twenty nanometers.

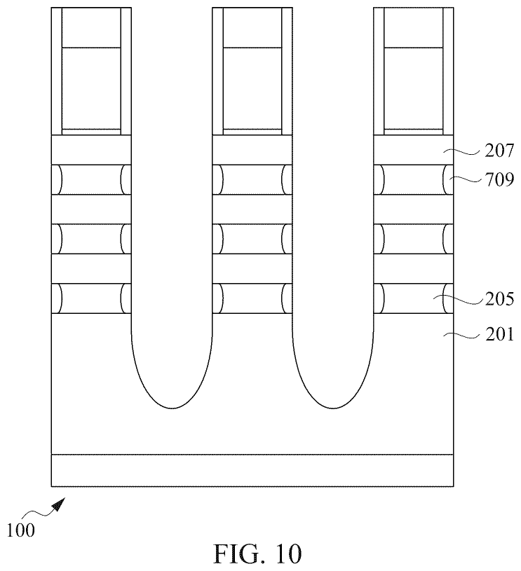

As further shown in FIG. 10, method 1000 (FIG. 2) includes forming inners spacers 709 at operation S1080. For example, operation S1080 may include laterally etching the epitaxial layers 205 of the second composition. In an exemplary embodiment, an SiGe etchback process is removed to laterally recess the layers 205. As a result, pockets are formed laterally adjacent to the layers 205 and vertically adjacent to the layers 207. Then, a material for forming the inner spacers 709 is deposited. For example, the inner spacers 709 may be formed from silicon oxides, silicon nitrides, silicon carbides, silicon carbide nitride, silicon oxide carbide, silicon carbide oxynitride, and/or other suitable dielectric materials. The inner spacers 709 may be formed by ALD or any other suitable method. As shown, after deposited the material forming inner spacers 709, the material may be trimmed from the sidewalls of epitaxial layers 207.

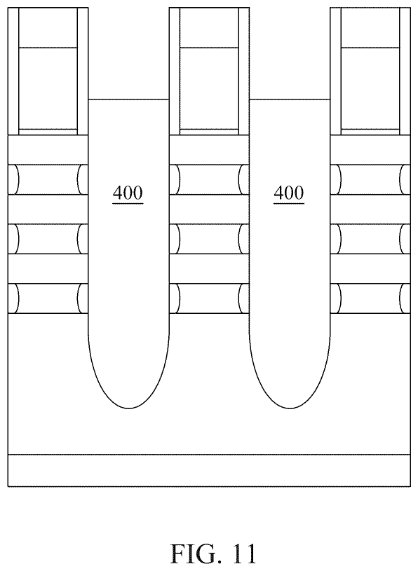

The method may continue, at operation S1090, with forming source/drain features 400, as shown in FIG. 11. In exemplary embodiments, the source/drain features 400 are formed by epitaxial growth. In exemplary embodiments, the source/drain features 400 are strained source/drain features 400.

In exemplary embodiments, the source/drain features 400 may include an n-type epitaxial material source/drain features and a p-type epitaxial material source/drain features. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

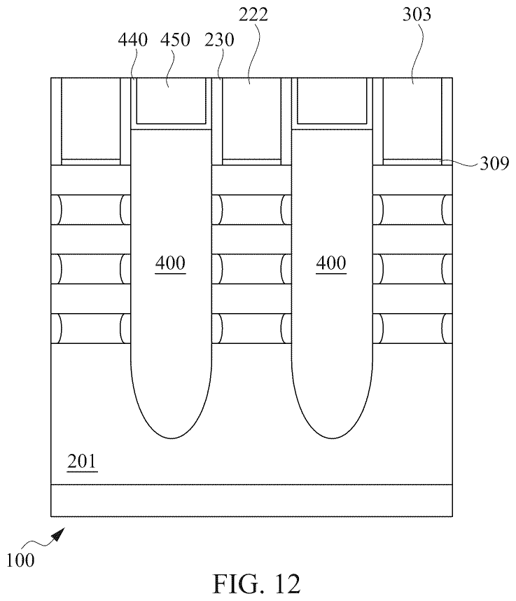

In FIG. 12, method 1000 includes, at operation S1100, capping the source/drain features 400 with dielectric. Specifically, a dielectric liner 440 may be formed over source/drain features 400 and along the sides of the spacers 230. Further, a dielectric 450 may be formed over the liner 440 over the source/drain features 400. In exemplary embodiments, the dielectric 450 is a first interlayer dielectric layer (ILD). The dielectric 450 may be silicon oxide or other suitable dielectric material. In certain embodiments, the ILD dielectric 450 is the same material as the sidewall spacers 230. In certain embodiments, the dielectric liner 440 is a dielectric, such as silicon nitride or another suitable material.

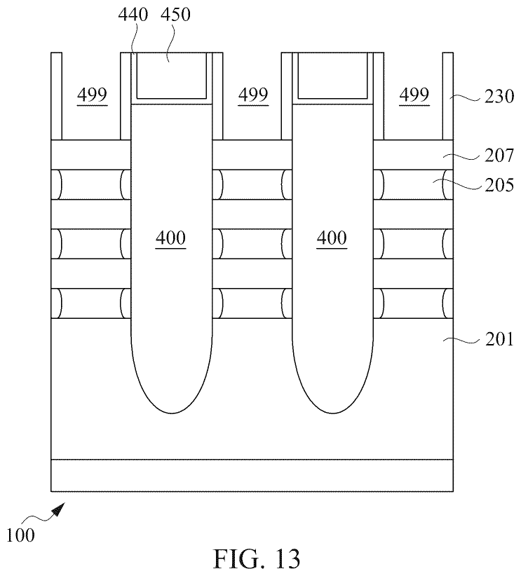

As further shown in FIG. 13, method 1000 includes, at operation S1110, opening and removing the sacrificial gate structures 222, including removing both the sacrificial gate dielectric 309 and the sacrificial gate electrode 303. Specifically, a chemical mechanical planarization (CMP) process may be performed to remove the mask layer 225 and to uncover the sacrificial gate structures 222. Further, the sacrificial gate structures 222 are removed to form gate cavities 499. As shown, the gate cavities 499 are bounded by the sidewall spacers 230.

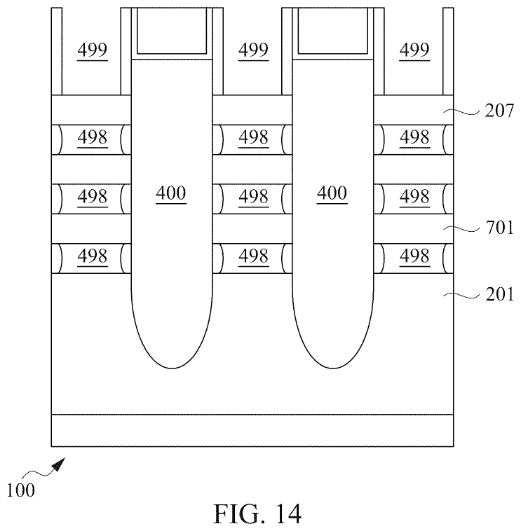

In FIG. 14, method 1000 removes the interposer epitaxial layers 205 at operation S1120. As a result, gaps 498 are formed between the epitaxial layers 207 of the first composition. In this manner, the epitaxial layers 207 of the first composition are formed as vertically-spaced apart semiconductor nanosheets 701.

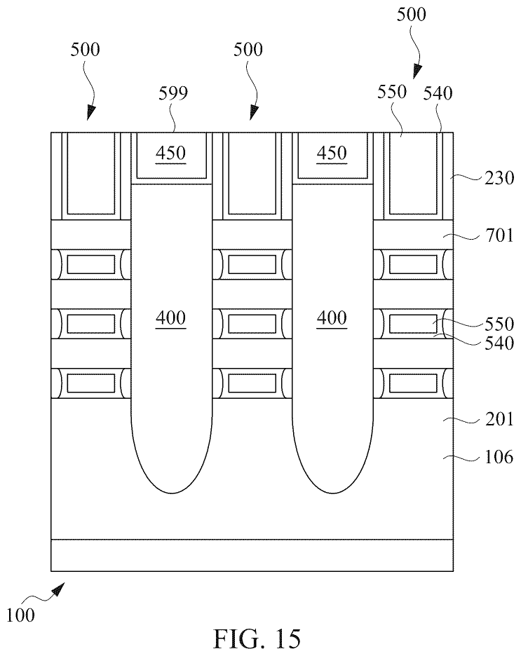

In FIG. 15, method 1000 includes, at operation S1130, completing a replacement metal gate process to form metal gate structures 500.

In exemplary embodiments, the replacement metal gate process includes forming a gate dielectric layer 540 in the gate cavities 499 and in the gaps 498 under nanosheets 701, and forming a gate electrode material 550 over the gate dielectric layer 540 to fill the gate cavities 499 and fill the gaps 498.

An exemplary gate dielectric layer(s) 540 is deposited conformally. The gate dielectric 540 may be formed on the semiconductor nanosheets 701, and the gate electrode material 550 may be formed on the gate dielectric layer(s) 540. Thus, each semiconductor nanosheet 701 is wrapped in gate dielectric 540 and surrounded by gate electrode material 550.

In accordance with some embodiments, the gate dielectric layer(s) 540 comprises silicon oxide, silicon nitride, or multilayers thereof. In some embodiments, the gate dielectric layer(s) 540 is a high-k dielectric material, and in these embodiments, the gate dielectric layer(s) 540 may have a k value greater than about 7.0, and may include a metal oxide or a silicate of Hf, Al, Zr, La, Mg, Ba, Ti, Pb, and combinations thereof. The formation methods of the gate dielectric layer(s) 540 may include Molecular-Beam Deposition (MBD), ALD, PECVD, and the like.

The gate electrode material 550 is deposited over the gate dielectric layer(s) 540 and fills the remaining portion of the gate cavity. The gate electrode material 550 may be a metal-containing material such as TiN, TaN, TaC, Co, Ru, Al, combinations thereof, or multi-layers thereof. For example, although a single gate electrode material is illustrated, any number of work function tuning layers may be deposited.

As shown, the FIG. 15, the replacement metal gate process further includes removing excess portions of the gate dielectric layer(s) 540 and the gate electrode material 550 located over the top surface of the ILD 450. For example, a planarization process, such as a CMP process, may be performed to remove the excess portions of the gate dielectric layer(s) 540 and the gate electrode material 550. As a result, the device 100 has an upper surface 599. The remaining portions of material of the gate dielectric layer(s) 540 and the gate electrode material 550 thus form the replacement metal gate structure 500 of the resulting device 100. The gate dielectric layer(s) 540 and gate electrode material 550 may be collectively referred to as a “gate,” a “gate stack,” or a “gate structure.” Each gate structure 500 may extend along sidewalls of a channel region of the fin structures.

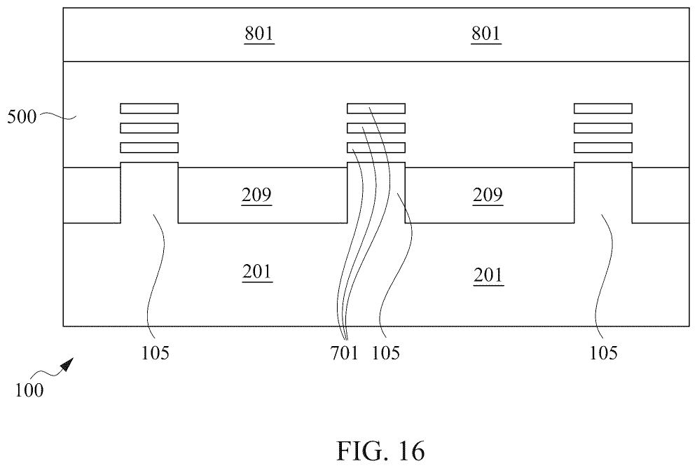

FIG. 16 is a Y-cut cross-sectional view taking along a gate 500. As shown in FIG. 16, an optional gate capping layer 801 may be formed over the gates 500.

The optional gate caps 801 may be formed by initially depositing a dielectric material over the gates. In some embodiments, the gate caps 801 are formed using a dielectric material such as a silicon nitride (SiN), oxide (OX), silicon oxynitride (SiON), silicon oxycarbonitride (SiOCN), silicon carbonitride (SiCN), or the like. According to some embodiments, the gate caps 801 are formed using a metal oxide of materials such as zirconium (Zr), hafnium (Hf), aluminum (Al), or the like. Furthermore, the gate caps 801 may be formed using a suitable deposition process such as chemical vapor deposition (CVD), atomic layer deposition (ALD), physical vapor deposition (PVD), combinations of these, or the like. However, any suitable materials and deposition processes may be utilized. After being deposited, the gate caps 801 may be planarized using a planarization process such as a chemical mechanical polishing process.

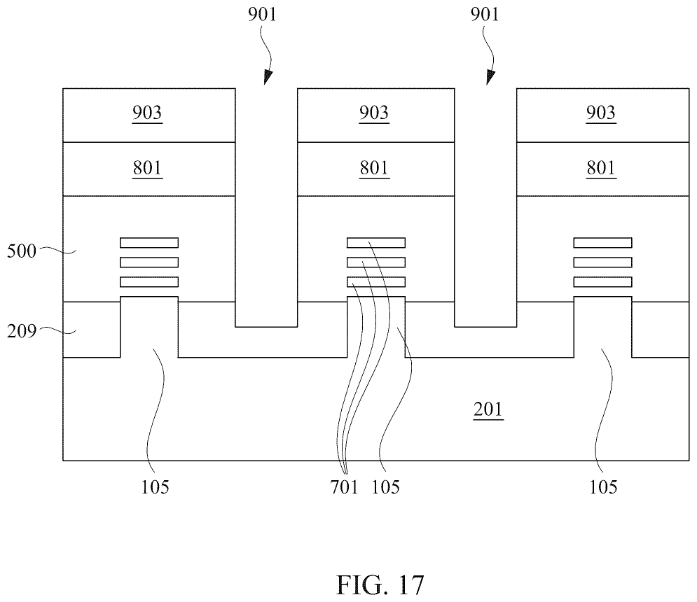

FIG. 17 is a Y-cut cross-sectional view taking along a gate 500. Cross-referencing FIGS. 1 and 17, method 1000 may continue, at operation S1140, with forming openings 901 in the gates 500, in accordance with some embodiments. After the gate caps 801 have been planarized, a masking layer 903 may be deposited over the planar surfaces of the gate caps 801. After being deposited, the masking layer 903 is patterned to expose the underlying materials including the gate caps 801 in desired locations of dielectric structures 110 that are to be formed.

After being patterned, the masking layer 903 is used as an etching mask to etch the underlying materials to form the openings 901 (e.g., trenches, recesses, channels or the like). In the etching process, the materials of the gate caps 801 and the gates 500 are etched using an anisotropic etching process. In certain embodiments, the etch process continues through the gate dielectric 540 and into the isolation regions 209. The openings 901 may be formed between adjacent fins 105 and may be formed to cut through one or more gates 500. According to some embodiments, two of the openings 901 are formed to cut through two adjacent gates 500 and are located on opposite sides of one or more of the fins 105, e.g., selected fin(s), as shown in FIG. 2. After the openings 901 have been formed, the masking layer 903 is removed.

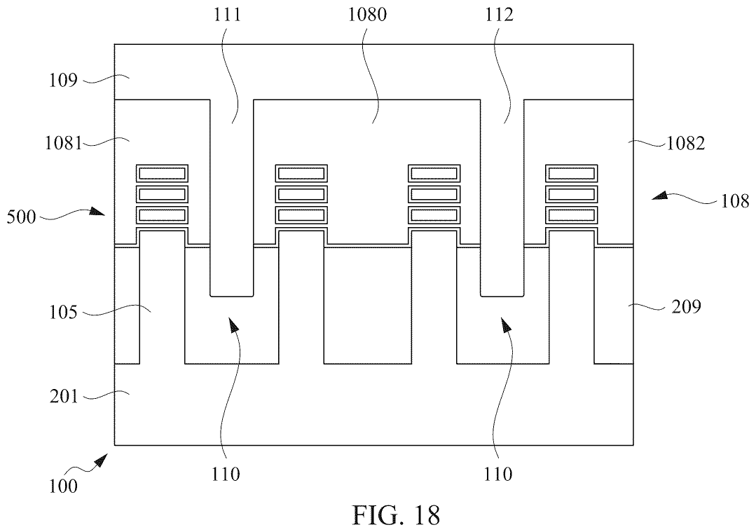

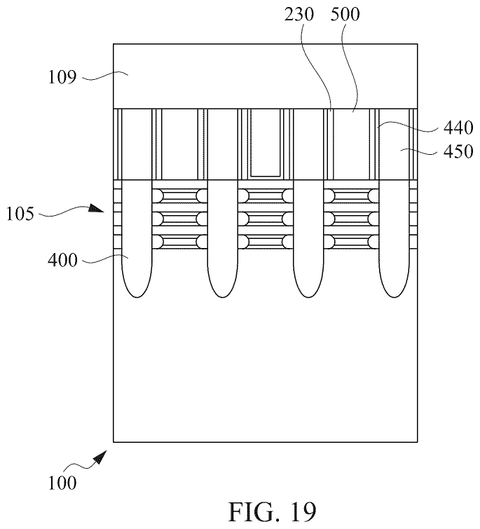

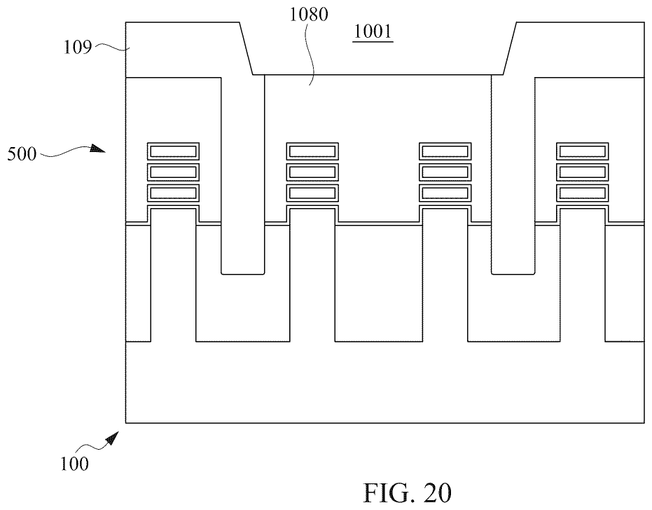

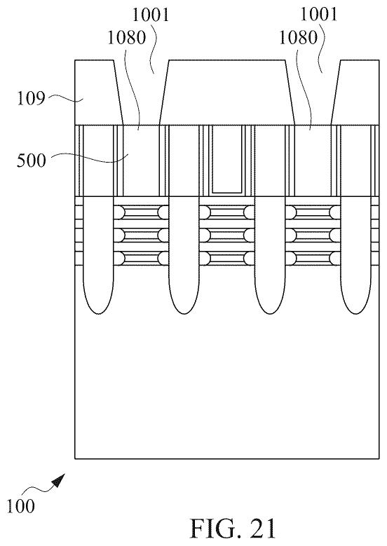

Cross-referencing FIG. 1 and FIGS. 18 and 19, method 1000 may continue, at operation S1150, with forming dielectric walls 110 from dielectric material 109, in accordance with some embodiments. FIG. 18 is a Y-cut cross-sectional view taken along a gate 500 and across four fins 105 and FIG. 19 is an X-cut cross-sectional view taken along a fin 105 and across four gates 500. FIGS. 20, 22, 24, 26, and 28 are Y-cut cross-sectional views similar to FIG. 18; and FIGS. 21, 23, 25, 27, and 29 are X-cut cross-sectional views similar to FIG. 19 and at the same stage of fabrication as the preceding Y-cut cross-sectional view.

After the openings 901 have been formed, masking layer 903 may be removed. Then, the dielectric walls 110 are formed by initially depositing a dielectric material 109 to fill and overfill the openings 901. In accordance with some embodiments, the dielectric material 109 is formed using any dielectric material and deposition process suitable for forming the gate caps 801. In some embodiments, the dielectric material 109 is the same as the dielectric material used to form the gate caps 801, although the dielectric materials may be different. In the embodiment of FIG. 18, the optional gate caps 801 are not present, or may be considered to be part of the dielectric material 109. For example, in embodiments where the gate caps 801 are formed using silicon nitride (SiN), dielectric material 109 may also be silicon nitride (SiN) formed in a deposition process such as Atomic Layer Deposition (ALD). However, any suitable dielectric materials and deposition processes may be used. According to some embodiments, the dielectric walls 110 are formed with a width between adjacent gate segments 108 of from about 5 nm to about 50 nm, such as about 10 nm. However, any suitable widths may be used.

As shown, the dielectric walls 110 extend into the STI regions 209 and divide the gates, which are relatively long, into a plurality of gate segments 108 which are relatively short. The dielectric walls 110 may be used to isolate the gate segments 108 from one another. Furthermore, the excess dielectric material 109 of the dielectric walls 110 outside of the openings 901 may be retained and used as a masking layer during later etching.

In FIG. 18, a first dielectric wall 111 separates a first gate segment 1081 from a selected gate segment 1080. Further, a second dielectric wall 112 separates a second gate segment 1082 from a selected gate segment 1080.

FIG. 19 illustrates that the gates 500 are formed between sidewall spacers 230. As described above, the sidewall spacers 230 are initially formed around sacrificial gates. The sidewall spacers 230 may include spacer material such as silicon oxide, silicon nitride, silicon carbide, silicon oxynitride, SiCN films, silicon oxycarbide, SiOCN films, and/or combinations thereof. By way of example, the sidewall spacers 230 may be formed by depositing spacer material including a liner material layer and a dielectric material layer over the sacrificial gate structure 222 using processes such as a subatmospheric CVD (SACVD) process, a flowable CVD process, an ALD process, a PVD process, or other suitable process respectively. In certain embodiments, the sidewall spacers 230 are low-k silicon oxide.

As shown in FIG. 19, source/drain features 400 have been formed in areas recessed from the fin 105. Typically, the fin 105 is recessed in areas not covered by the sacrificial gate. Then, epitaxial material is grown in the recesses to form the source/drain features 400. After the source/drain features 400 are formed, they are capped with dielectric material. For example a dielectric liner 440 may be formed on the sidewall spacers 230. Also, a dielectric 450 may be formed over the liner 440 and over the source/drain features 400. In exemplary embodiments, the dielectric 450 is a first interlayer dielectric layer (ILD). The dielectric 450 may be silicon oxide or other suitable dielectric material. In certain embodiments, the dielectric liner 440 is a dielectric, such as silicon nitride or another suitable material. After formation of the ILD 450, the sacrificial gates are removed and replaced with the gates 500 as shown.

Cross-referencing FIG. 1 and FIGS. 20 and 21, method 1000 may continue, at operation S1160, with forming an opening 1001 in the dielectric material 109 over each segment 1080 of gate 500 to be removed in an initial step of forming an insulation feature, in accordance with some embodiments.

In certain embodiments, forming the opening 1001 in the dielectric material 109 may include depositing a variety of masking layers, such as including a carbon based bottom layer, an oxide based middle layer, and an extreme ultraviolet (EUV) photo resist top layer. The process may include performing an extreme ultraviolet lithography (EUV) photo resist exposure technique to pattern the photo resist, followed by etching of the middle layer and bottom layer. Then, the dielectric material 109 is etched to form the opening 1001. The dielectric material 109 may be etched by a dry etch process, such as a process suitable for etching a silicon nitride material.

Photo resist and other patterning materials (middle layer, spin-on glass or bottom layer, spin-on carbon) for EUV lithography may be removed after hard mask open, such as by in-situ or ex-situ ashing process.

Cross-referencing FIG. 1 and FIGS. 22 and 23, method 1000 may continue, at operation S1170, with removing the gate segment 1080.

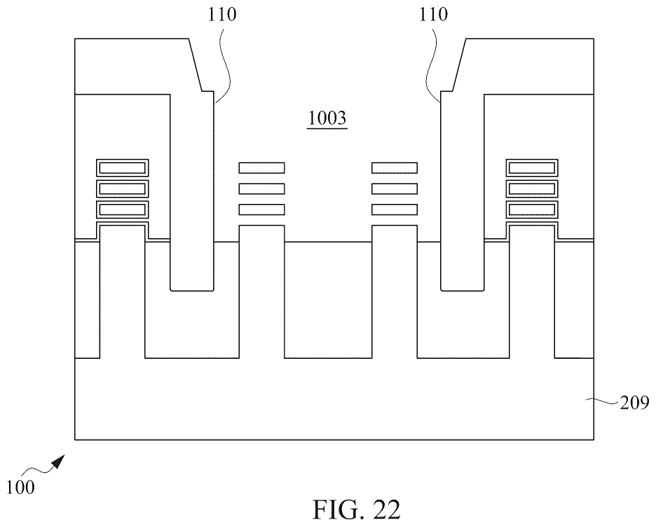

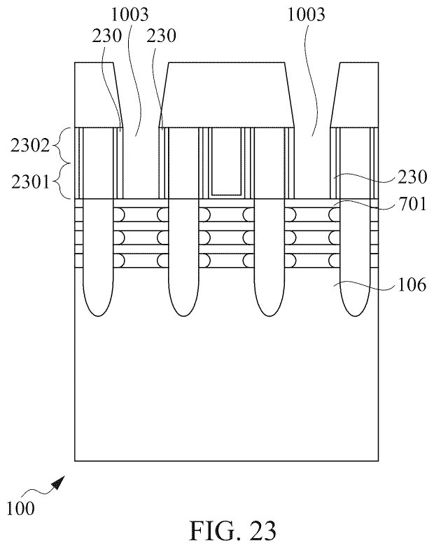

In certain embodiments, removing the gate segment 1080 forms an opening 1003 and includes selectively removing the gate segment 1080, including the gate material 500 and gate dielectric 540. The gate segment 1080 may be removed by a dry or wet etch. In certain embodiments, the process may remove all of the gate segment 1080 between the dielectric walls 110 and over the STI regions 209, as shown in FIG. 22. Further, the process may remove all of the gate segment 1080 between the sidewall spacers 230 and over the mesa or base portion 106 of fins 105, including between nanosheets 701, as shown in FIG. 23.

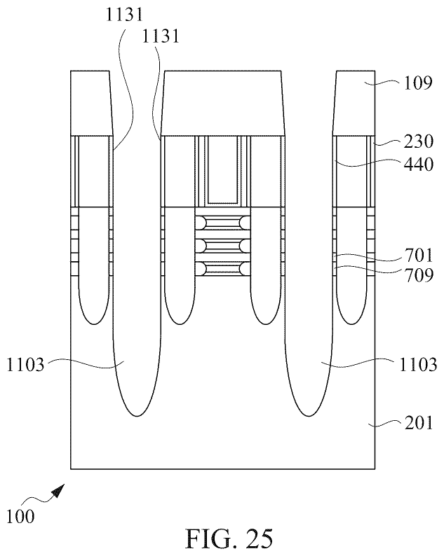

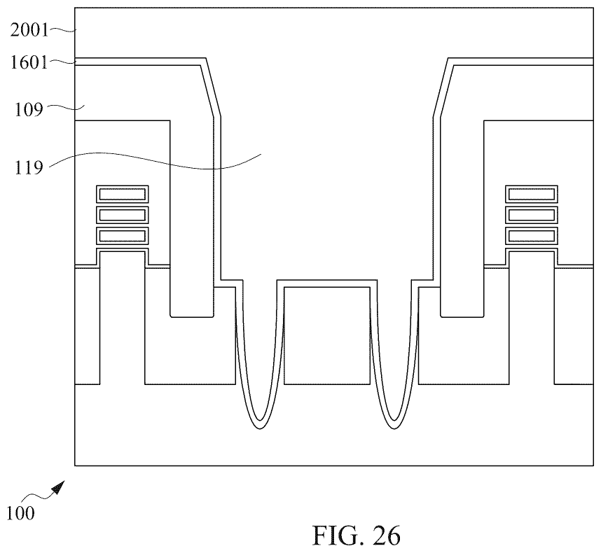

Cross-referencing FIG. 1 and FIGS. 24 and 25, method 1000 may continue, at operation S1180, with removing the nanostructures 701, etching the sidewall spacers 230, and recessing the selected fins 105 to form cavity or opening 1103. As shown in FIG. 25, the sidewall spacers 230 may be completely removed when forming the opening 1103.

After uncovering the nanostructures 701 and a portion of the fins 105 protruding above the isolation regions 209, further etching processes may be used to remove the materials of the nanostructures 701 and the sidewall spacers 230 and to recess the fins 105. In certain embodiments, the uncovered fins 105 and uncovered sidewall spacers 230 are removed, and a portion of the underlying substrate 201 is etched. As a result, an upper surface of the substrate 201 is recessed. As shown, the opening 1103 includes projections or fin cavities 1104 that extend through the STI region 209 and into the substrate 201.

In certain embodiments, the sidewall spacers 230 are removed by using oxide removal processes and/or by using low-k oxide selective sheet cut processes. As a result, edges 1131 of the opening 1103 are formed by the dielectric liner 440, nanosheets 701, inner spacers 709 and substrate 201. In other words, all of the sidewall spacers 230 between the edges 1131 and the dielectric liner 440.

In certain embodiments, the etch process is a plasma etch and may be followed by a wet clean process. The plasma etch may be tuned and controlled to remove the material of the sidewall spacers 230. For example, the plasma etch may use halogen-based etchants, such as CF₄, CHF₃, CH₂F₂, CHF₃, or BCl₃). In some embodiments, HF and ammonia-based etchants with or without plasma enhancement may be used, such as to remove an oxide-based spacer 230.

Cross-referencing FIG. 1 and FIGS. 26 and 27, method 1000 may continue, at operation S1190, with forming an insulation feature 119 in the opening 1103.

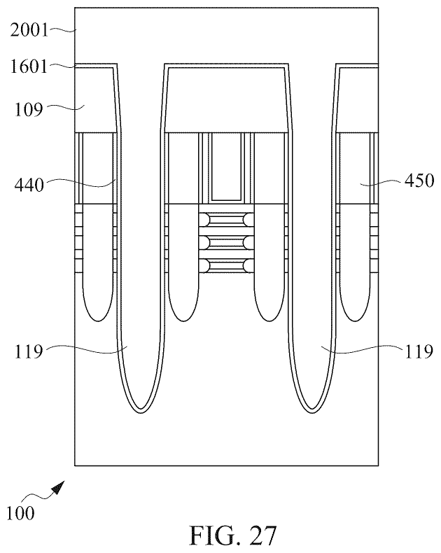

As shown, the insulation feature 119 may be formed by depositing a first insulating dielectric material 1601 in the opening 1103. The first insulating dielectric material 1601 may be formed as a liner that completely covers the surfaces of the openings 1103, and over the top surface of the dielectric material 109. As shown in FIG. 27, the first insulating dielectric material 1601 contacts the dielectric liner 440.

In certain embodiments, the first insulating dielectric material 1601 may include silicon oxide, oxynitride, a dielectric material having a dielectric constant (k) lower than silicon oxide (therefore referred to as low-k dielectric material layer), and/or other suitable dielectric material layer. In certain embodiments, the first insulating dielectric material 1601 is low-k silicon oxide.

Further, the insulation feature 119 may be formed by depositing a second insulating material 2001 over the first insulating material 1601. The second insulating material 2001 may completely fill the opening 1103.

In certain embodiments, the second insulating dielectric material 2001 may include silicon nitride, oxynitride, and/or other suitable dielectric material layer. In certain embodiments, the second insulating dielectric material 2001 is silicon nitride.

In certain embodiments, the second insulating dielectric material 2001 may be deposited with a refill process. In one example, the dielectric material 2001 may be deposited by chemical vapor deposition (CVD), atomic layer deposition (ALD), spin-on coating, or other suitable techniques. As shown, the second insulating dielectric material 2001 may be first formed as a blanket layer covering the surface of the dielectric material 109.

Cross-referencing FIG. 1 and FIGS. 28 and 29, operation S1190 may further include planarizing the structure of device 100 to form the insulation feature 119 in the opening 1103.

As shown, the planarization process may remove all of the overburden portions of the dielectric material 109, the first insulating material 1601, and the second insulating dielectric material 2001 and form the structure of device 100 with an upper surface 2101.

Because the sidewall spacers 230 adjacent to the insulation feature 119 were removed, the upper surface 2101 at the insulation feature 119 is formed by the second insulating layer 2001, the first insulating layer 1601, the dielectric liner 440 and the ILD dielectric 450, in order. For example, between two ILD dielectric structures 450 surrounding an insulation feature 119, the upper surface 2101 is formed by ILD dielectric structure 450, dielectric liner 440, first insulating layer 1601, second insulating layer 2001, first insulating layer 1601, dielectric liner 440, and ILD dielectric structure 450.

Operation S1190 may be considered to complete the insulation feature fabrication process by forming the insulation feature 119 including first insulating dielectric material 1601 and second insulating dielectric material 2001.

As shown in FIG. 1, method 1000 may include further processing. For example, various lithography, patterning, and passivation processes may be performed to form dielectric and metallization layers and to form a desired interconnect structure, such as in typical Back-end-of-line (BEOL) processing. For example, an ILD structure over a source/drain feature 400 may be removed and replaced with a conductive material for forming a source/drain interconnect.

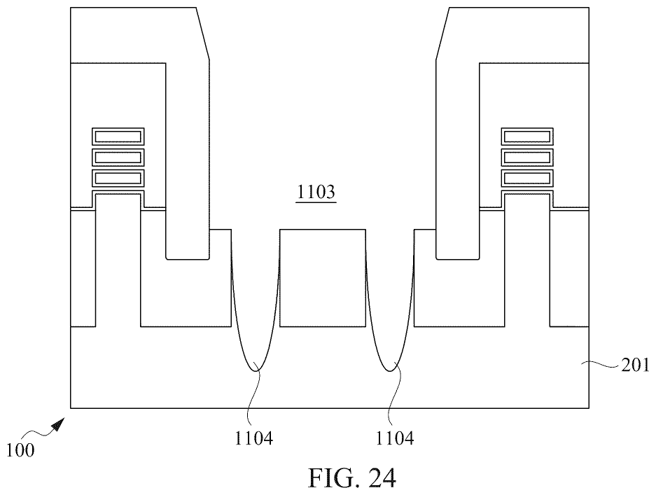

While FIGS. 24-29 illustrate an embodiment in which all of the sidewall spacer 230 is removed when forming openings 1103 during operations S1160-S1180, other embodiments are contemplated. For example, only a portion of each sidewall spacer 230 may be removed.

For example, referring to FIG. 1 and FIG. 30, operation S1180 may process the structure of FIGS. 22-23 by performing an etch process to remove the nanostructures 701, partially etch the sidewall spacers 230, and recess the selected fins 105 to form cavity or opening 1103. As shown in FIG. 30, the sidewall spacers 230 are only partially removed when forming the opening 1103.

Specifically, the etch process is tuned and controlled to completely remove an upper portion 2302 (labeled in FIG. 23) of the sidewall spacers 230 while a lower portion 2301 of the sidewall spacers 230 remains. For example, the etch process may use directional plasma etch steps using halogen-based chemicals, such as CF₄, CHF₃, CH₂F₂, CHF₃, or BCl₃. In some embodiments, etch conditions with low pressure (such as at a pressure of below 100 mT) and high bias power (such as above 300 W) may be used to enhance the directionality of the plasma to precisely control the recess of sidewall spacers 230 to remove upper portion 2302.

For example, after uncovering the nanostructures 701 and a portion of the fins 105 protruding above the isolation regions 209, further etching processes may be used to remove the materials of the nanostructures 701, remove the upper portion 2301 of the sidewall spacers 230, and to recess the fins 105. In certain embodiments, the uncovered fins 105 are removed, the uncovered sidewall spacers 230 are partially etched, and a portion of the underlying substrate 201 is etched. As a result, an upper surface of the substrate 201 is recessed.

In certain embodiments, the sidewall spacers 230 are partially removed by using oxide removal processes and/or by using low-k oxide selective sheet cut processes. As a result, edges 1131 of the opening 1103 are formed by the dielectric liner 440, the lower portions 2301 of sidewall spacers 230, nanosheets 701, inner spacers 709 and substrate 201.

In certain embodiments, the etch process is a plasma etch and may be followed by a wet clean process. The plasma etch is tuned and controlled to remove only the upper portion 2302 of the sidewall spacers 230.

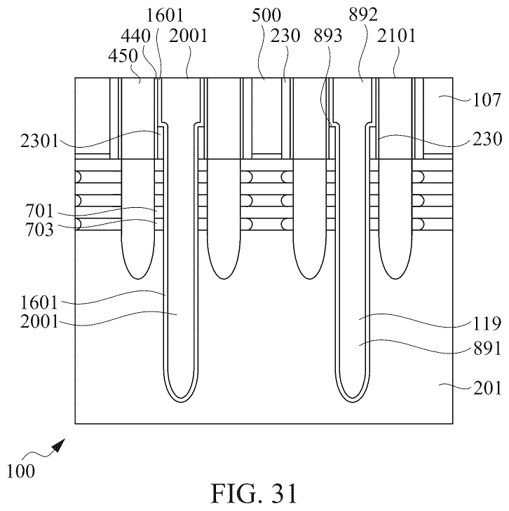

Referring to FIG. 1 and FIG. 31, operation S1190 may process the structure of FIG. 30 by forming an insulation feature 119 in the opening 1103. For example, first insulating layer 1601 and second insulating layer 2001 may be deposited and planarized as described above. As a result, device 100 is formed with an upper surface 2101.

Because the upper portions 2302 of sidewall spacers 230 adjacent to the insulation feature 119 were removed, the upper surface 2101 at the insulation feature 119 is formed by the second insulating layer 2001, the first insulating layer 1601, the dielectric liner 440 and the ILD dielectric 450, in order. For example, between two ILD dielectric structures 450 surrounding an insulation feature 119, the upper surface 2101 is formed by ILD dielectric structure 450, dielectric liner 440, first insulating layer 1601, second insulating layer 2001, first insulating layer 1601, dielectric liner 440, and ILD dielectric structure 450.

In the embodiment of FIGS. 30-31, the insulation feature 119 formed with a furnace-shaped cross-section. Specifically, the insulation feature 119 includes a lower section 891 and an upper section 892. The lower section 891 and upper section 892 abut at a laterally-outward extending shoulder 893. The upper section 892 has a wider cross-sectional width than the lower section 891.

Operation S1190 may be considered to complete the CMODE process by forming the insulation feature 119 in the form of a CMODE structure, including first insulating dielectric material 1601 and second insulating dielectric material 2001.

It is noted that while in the embodiments of FIGS. 20-29 and FIGS. 30-31, the etching process removes the gate 500 before the sidewall spacers 230 are etched, other embodiments are contemplated. For example, the etch process to remove the gate 500 may also etch or partially etch the sidewall spacers 230. In such an embodiment, the etch process to remove the nanosheets 701 and etch the substrate 201 may also partially etch the sidewall spacers 230, or the etch process to remove the nanosheets 701 and etch the substrate 201 may not include etching the sidewall spacers 230.

While the operations of method 1000 with regard to FIGS. 1-31 are described in a Continuous Metal On Diffusion Edge (CMODE) process, in which the insulation feature 119 is formed after the metal gate is formed, the insulation feature 119 may be formed in a Continuous Poly On Diffusion Edge (CPODE) process, i.e., before the metal gate is formed.

Specifically, in the illustrated CMODE process, the gate segment being removed is a metal gate segment and the gate dielectric is a high-k gate dielectric. For a CMODE process, removal of the gate during operation S1190 includes removing the inter-sheet portions of the gate located under the nanosheets. In a CPODE process the gate being processed by operations S1160-S1190 is a dummy gate. In the CPODE process, the inter-sheet portions of the gate are not yet formed. Therefore, operation S1190 includes removing the sacrificial interposer first layers 205.

Method 1000, whether utilizing a CMODE process or CPODE process, removes or etches the sidewall spacers 230 during the process for removing the gate and/or during the succeeding process for removing the nanosheets and recessing the substrate. In other embodiments, the sidewall spacers 230 may be etched at a different stage of fabrication.

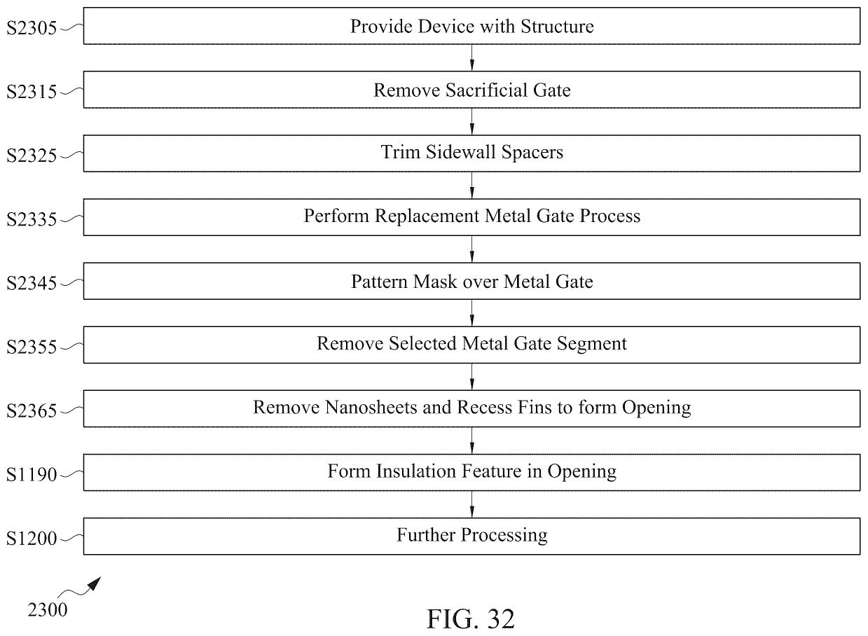

For example, FIG. 32 and FIGS. 33-37 illustrate an alternate method for etching the sidewall spacer 230 before the formation of the opening 1103.

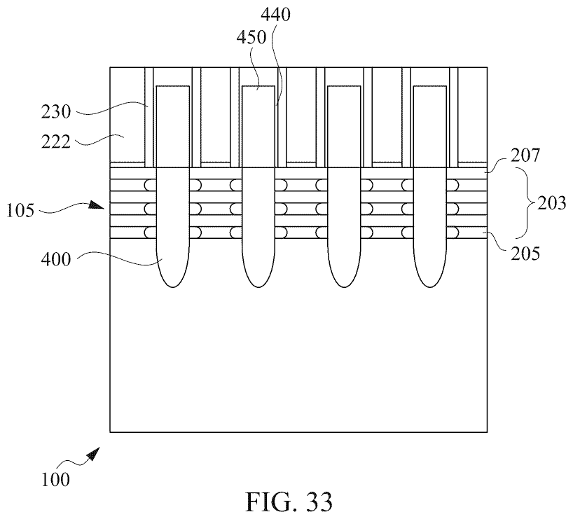

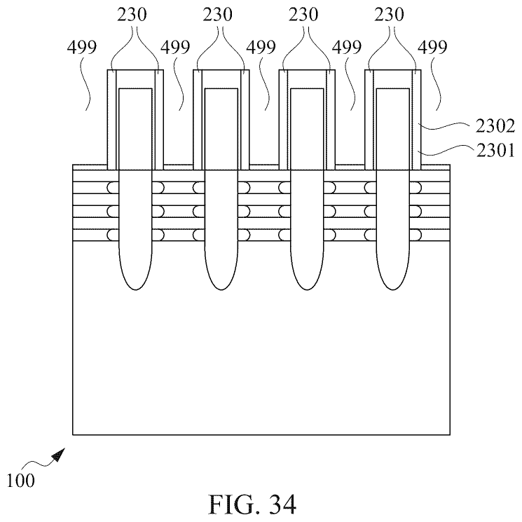

Referring to FIG. 32 and FIG. 33, method 2300 includes, at operation S2305, providing the structure of device 100 as shown in FIG. 33. A stack 103 of alternating layers 205 and 207 is patterned into a fin 105, sacrificial gates 222 are formed over the fin 105, sidewall spacers 230 are formed on sacrificial gates, non-covered portions of the fin 105 are recessed, source/drain features 400 are grown in the recesses, and ILD structures 440 and 450 are formed over the source/drain features 400. Operation S2305 may include operations S1010-S1100 above. Referring to FIG. 32 and FIG. 34, method 2300 further includes, at operation S2315, removing the sacrificial gate 222. Removal of the sacrificial gates 222 results in formation of gate cavities 499 located between sidewall spacers 230.

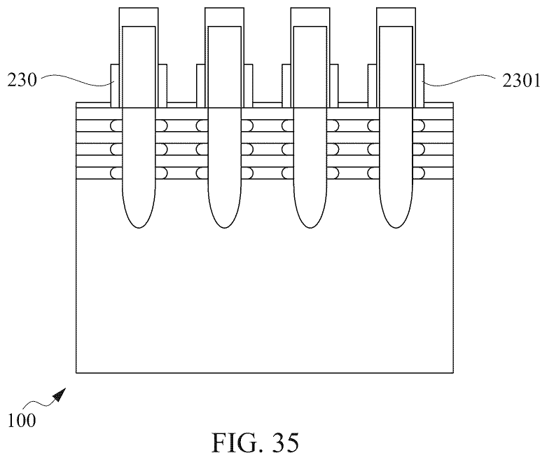

Referring to FIG. 32 and FIG. 35, method 2300 further includes, at operation S4005, trimming the sidewall spacers 230. Specifically, upper portions 2302 of the sidewall spacers 230 are removed, and only lower portions 2301 of the sidewall spacers 230 remain.

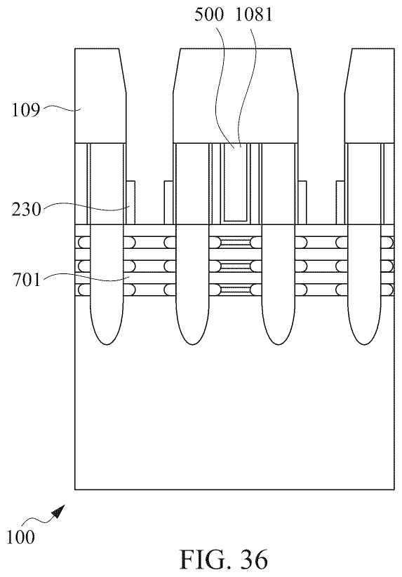

Referring to FIG. 32 and FIG. 36, a replacement metal gate process is performed at operation S2335 to remove sacrificial gates 222 and replace the sacrificial gates 222 with metal gates 500.

Method 2300 further includes, at operation S2345, forming an opening in a mask over selected metal gate segments 1080 (not shown in FIG. 36). Specifically, mask 109 may be formed over the metal gates 500 and patterned to cover gate segment 1081, similar to operation S1160 above.

Method 2300 may continue at operation S2355 with removing the non-covered gate segment 1080, similar to operation S1170. In method 2300, because the sidewall spacers 230 have already been trimmed, the etching process to remove the metal gate segment 1080 need not etch the sidewall spacers 230.

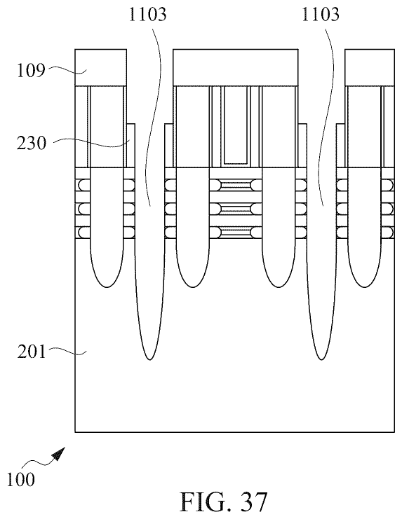

Referring to FIG. 32 and FIG. 37, method 2300 may continue at operation S2365 with removing the nanostructures 701 and recessing the selected fins 105 to form cavities or openings 1103, similar to operation S1180 above. However, in method 2300, because the sidewall spacers 230 have already been trimmed, the etching process to remove the nanostructures 701 and recess the selected fins 105 need not etch the sidewall spacers 230.

Method 2300 may continue with operations S1190 and S1200 as described above, to form the insulation feature 119 in the opening 1103 and perform further processing.

Thus, method 2300 may form a device 100 with insulation features 119 as shown in FIG. 31, in which lower sidewall spacer portions 2301 remain, but are distanced from the upper surface 2101 of the device 100, and separated from the surface 2101 of the device 100 by elements not formed from silicon oxide.

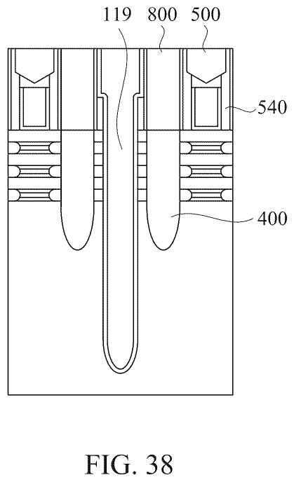

FIG. 38 illustrates the formation of an interconnect 800 to a source/drain feature 400. During this process, the ILD structure 450 (not shown) is etched and a conductive material is deposited to form the interconnect 800.

As shown in FIG. 38, the insulation feature is formed with a cross-sectional furnace shape, i.e., lower portions of sidewall spacers 230 are located next to the insulation feature 119 and upper portions of the sidewall spacers 230 have been removed. Further, the metal gate 500 is formed with a cross-sectional furnace shape. For example, upper portions of the gate dielectric 540 are partially etched such that the upper portion of the metal gate 500 has a greater lateral width than the lower portion of the metal gate 500 in the illustrated cross-sectional view.

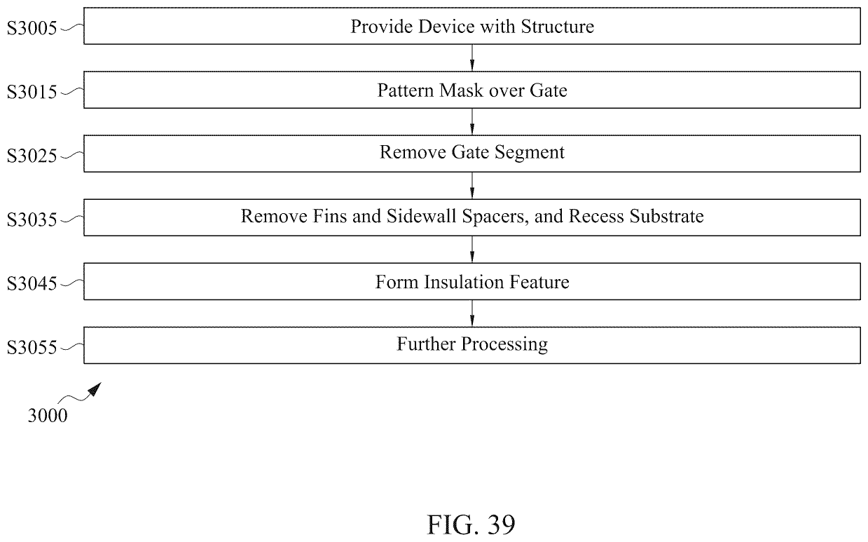

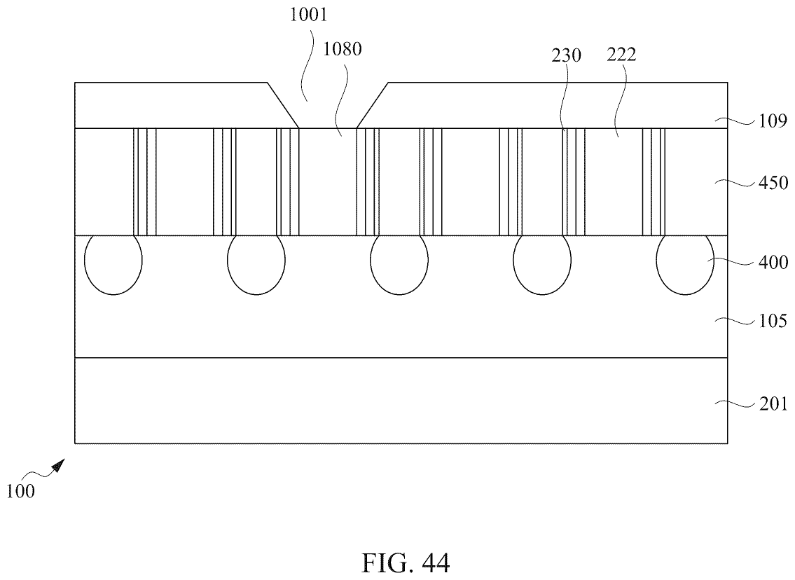

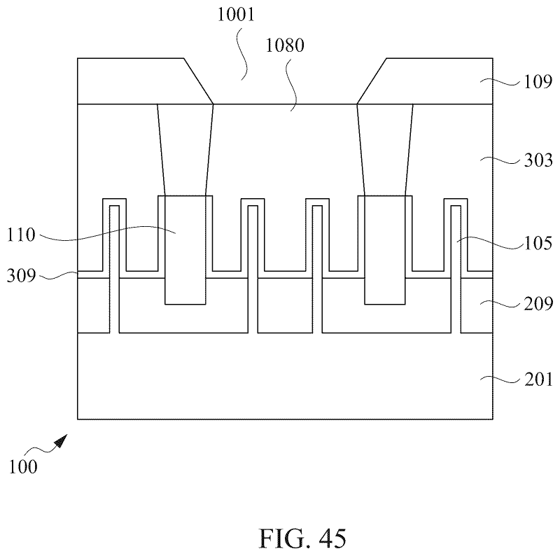

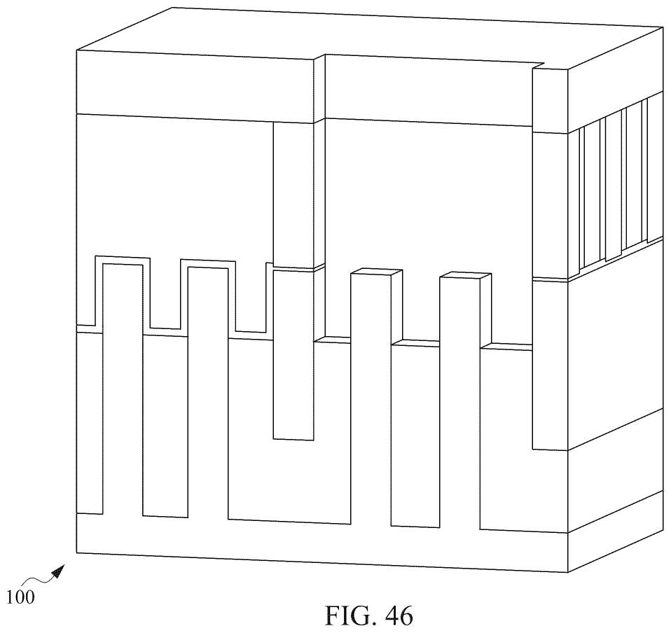

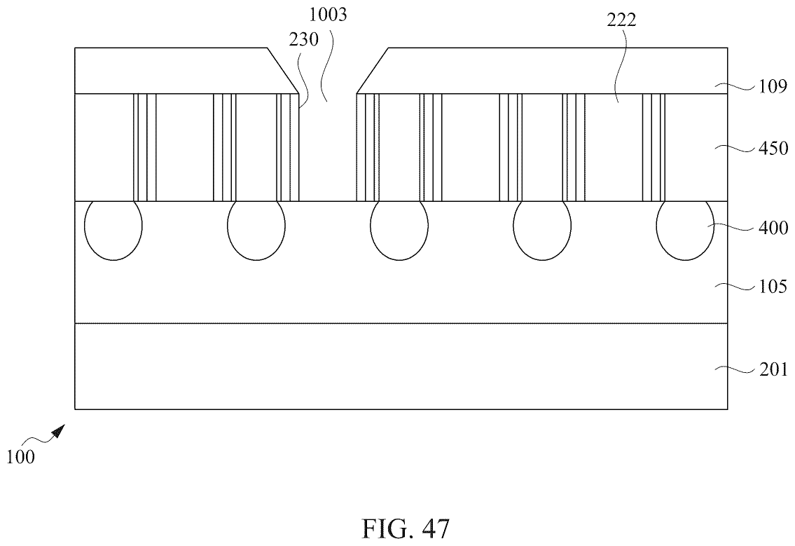

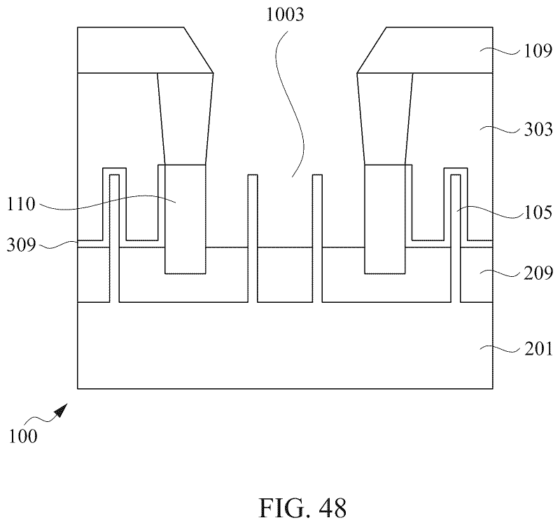

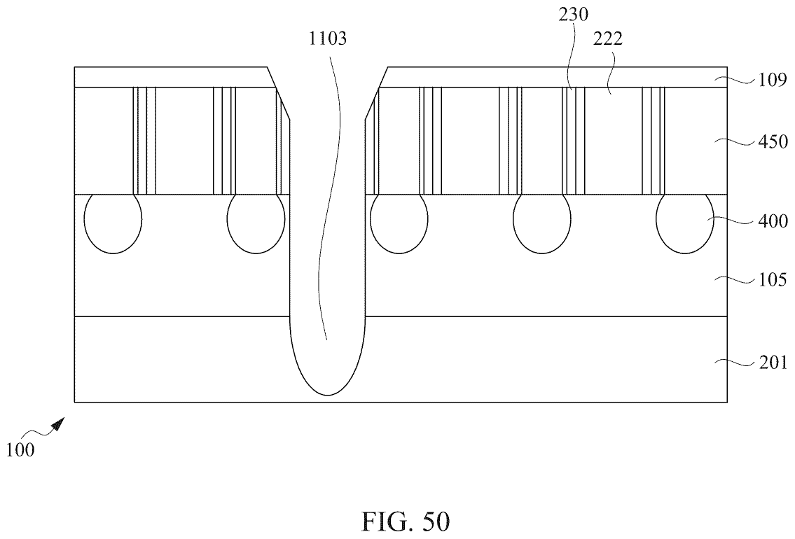

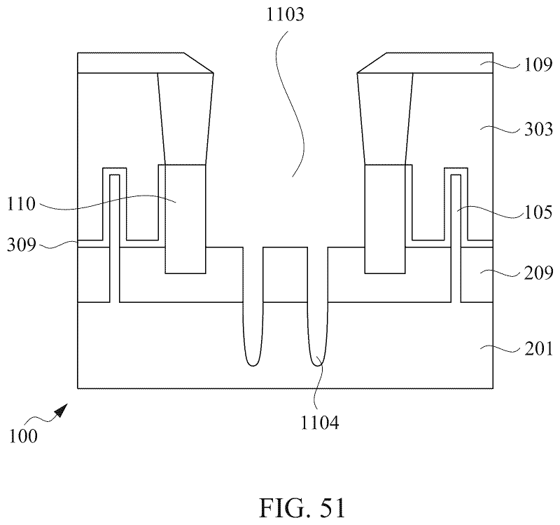

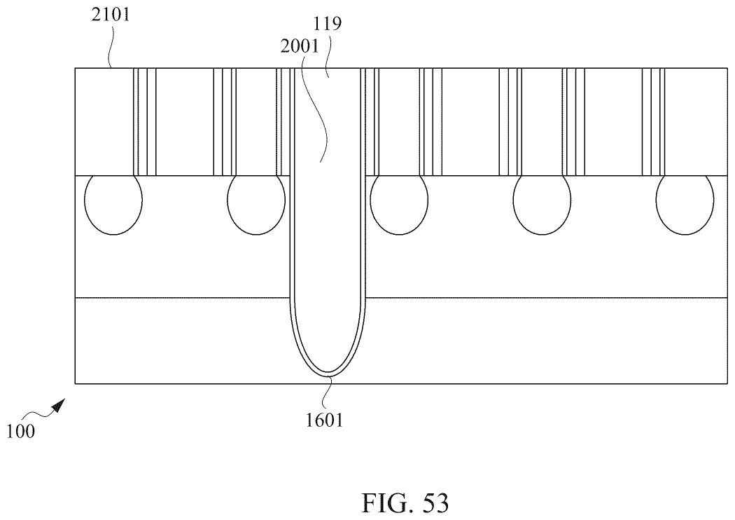

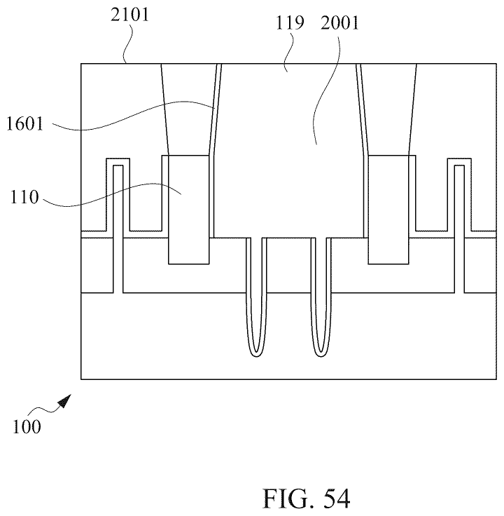

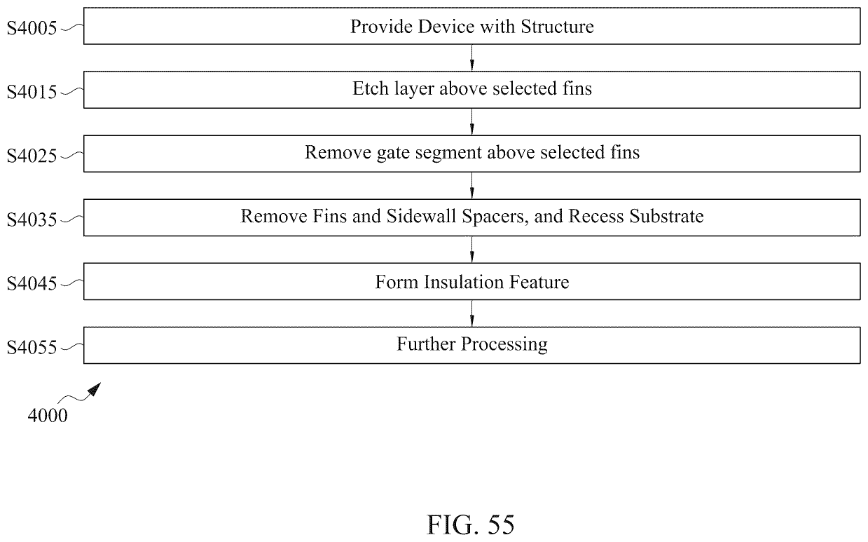

Referring now to FIG. 39 and FIGS. 40-54, another embodiment is described. Specifically, a method 3000 for forming an insulation feature 119 with a FinFET device 100 is described.

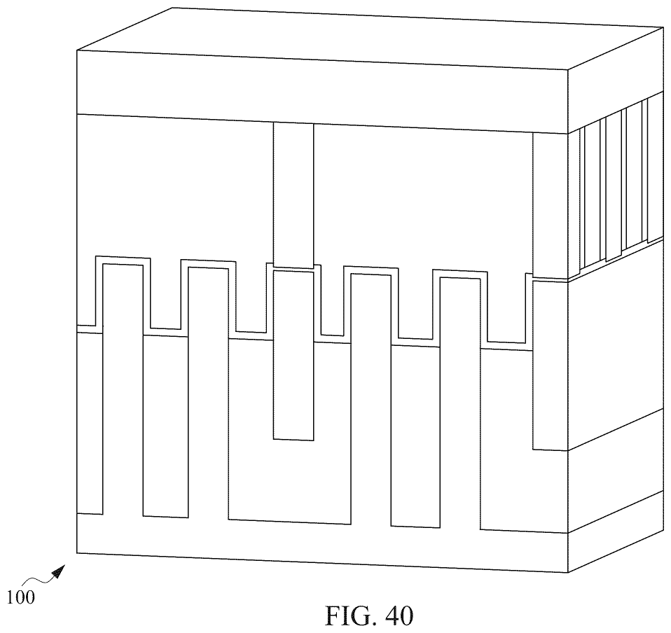

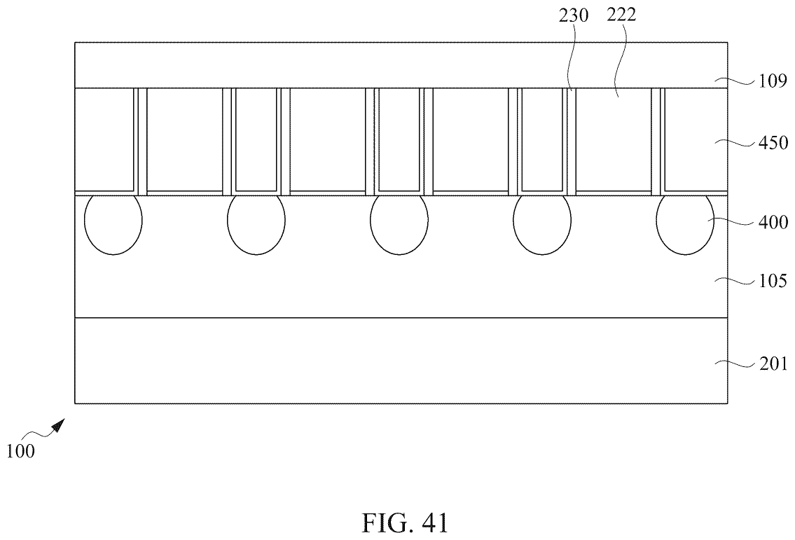

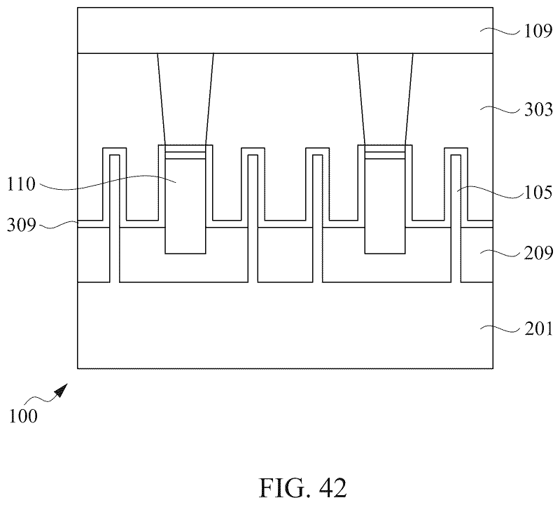

Cross-referencing FIG. 39 with FIGS. 40-42, method 3000 includes providing a device 100 with the FinFET structure at operation S3005. FIG. 40 provides a perspective view, FIG. 41 provides an X-cut cross-sectional view, and FIG. 42 provides a Y-cut cross-sectional view of a stage of fabrication. As shown, in the device 100, fins 105 are formed from and over a substrate 201; and STI features 209 are formed around the fins 105. Further, parallel gates 222 are formed over the fins 105, and source/drain features are formed in the fins 105 adjacent to the sacrificial gates 222. As shown, gate dielectric 309 may be formed over the STI features 209 before the sacrificial gate electrodes 303 are formed. As shown, dielectric structures 450 are formed over the source/drain features 400. As further shown, a mask 109, such as compressive silicon nitride is formed over the structure of the device 100.

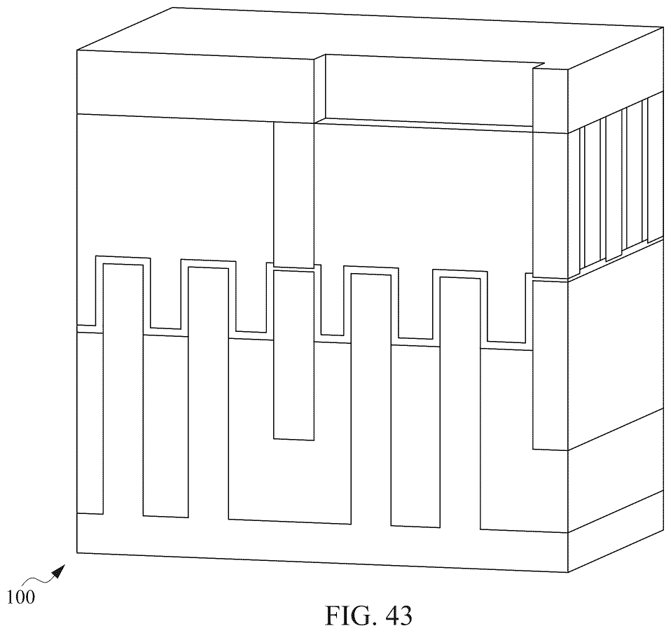

Cross-referencing FIG. 39 with FIGS. 43-45, method 3000 includes patterning a mask 109 over the gate 222 at operation S3015. Specifically, an opening 1001 is formed in the mask 109 over a selected gate segment 1080.

Cross-referencing FIG. 39 with FIGS. 46-48, method 3000 includes removing the selected gate segment 1080 at operation S3015. As a result, an opening 1003 is formed. As shown, operation S3015 removes the sacrificial gate electrode 303 and gate dielectric 309. As a result, selected fins 105 and surrounded STI features 209 are uncovered. The opening 1003 uncovers the oxide sidewall spacers 230.

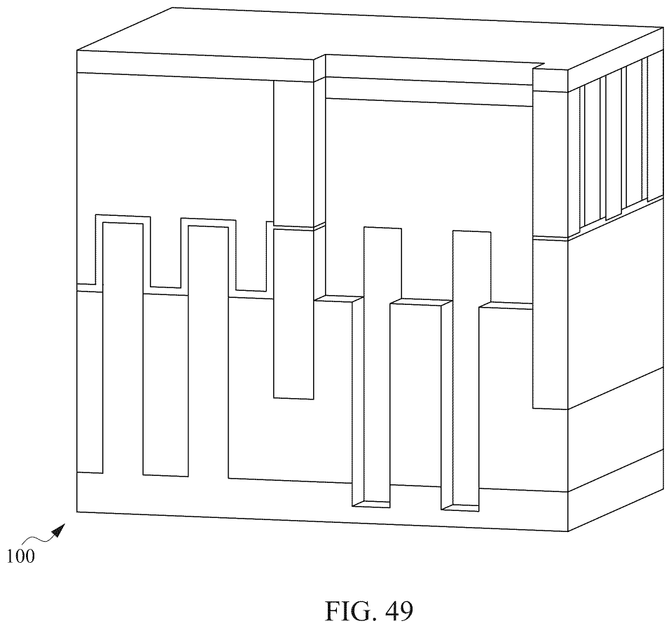

Cross-referencing FIG. 39 with FIGS. 49-51, method 3000 includes removing the selected fins 105, removing the sidewall spacers 230, and recessing the underlying substrate 201 to form openings 1103 at operation S3025.

As a result, an upper surface of the substrate 201 is recessed. As shown, the opening 1103 includes projections or fin cavities 1104 that extend through the STI region 209 and into the substrate 201.

In certain embodiments, the sidewall spacers 230 are removed by using oxide removal processes and/or by using low-k oxide selective sheet cut processes.

In certain embodiments, the etch process is a plasma etch and may be followed by a wet clean process. The plasma etch is tuned and controlled to remove the material of the sidewall spacers 230.

Cross-referencing FIG. 39 with FIGS. 49-51, method 3000 includes removing the selected fins 105, removing the sidewall spacers 230, and recessing the underlying substrate 201 to form openings 1103 at operation S3035.

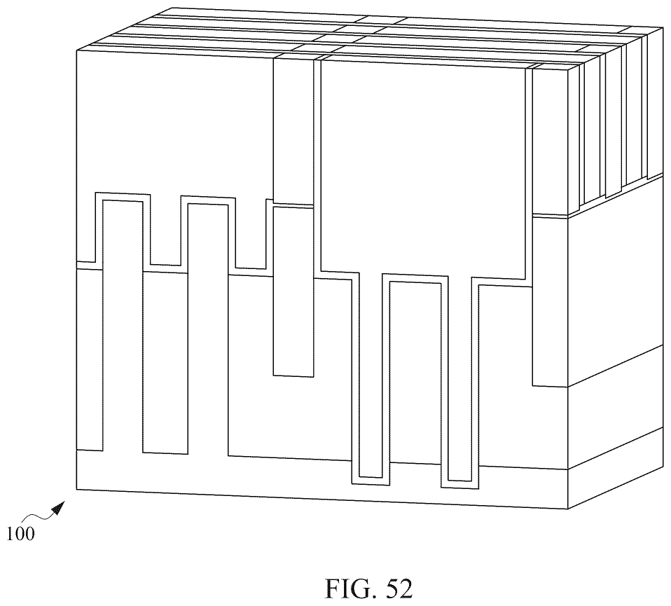

Cross-referencing FIG. 39 with FIGS. 52-54, method 3000 includes forming an insulation feature 119 in the opening 1103 at operation S3045. For example, a first insulating material 1601 may be formed as a liner that completely covers the surfaces of the openings 1103, and over the top surface of the dielectric material 109. In certain embodiments, the first insulating dielectric material 1601 may include silicon oxide, oxynitride, a dielectric material having a dielectric constant (k) lower than silicon oxide (therefore referred to as low-k dielectric material layer), and/or other suitable dielectric material layer. In certain embodiments, the first insulating dielectric material 1601 is low-k silicon oxide.

The second insulating material 2001 may be deposited over the first insulating material 1601. The second insulating material 2001 may completely fill the opening 1103. In certain embodiments, the second insulating dielectric material 2001 may include silicon nitride, oxynitride, and/or other suitable dielectric material layer. In certain embodiments, the second insulating dielectric material 2001 is silicon nitride.

In certain embodiments, the second insulating dielectric material 2001 may be deposited with a refill process. In one example, the dielectric material 2001 may be deposited by chemical vapor deposition (CVD), atomic layer deposition (ALD), spin-on coating, or other suitable techniques. As shown, the second insulating dielectric material 2001 may be first formed as a blanket layer covering the surface of the dielectric material 109.

As shown, operation S3045 further includes planarizing the structure of device 100 to form the insulation feature 119 in the opening 1103. Specifically, the dielectric material 109 and all of the overburden portions of the first insulating material 1601 and the second insulating dielectric material 2001 may be removed to form the structure of device 100 with an upper surface 2101.

Similar to the earlier described embodiments, the oxide sidewall spacers 230 are not located adjacent to the insulation feature 119 at the surface 2101, as the sidewall spacers 230 were removed when forming the openings for the insulation feature 119.

Method 3000 may continue with further processing at operation S3055. As the sacrificial gate 222 was etched to form the insulation feature 119. Method 3000 may continue with performing a replacement metal gate process to replace the remaining sacrificial gate with a metal gate. For example, the sacrificial gate is removed to form a gate cavity 499, and the metal gate 500 is formed in the gate cavity 499 as described above in relation to operations S1110-S1130.

Referring now to FIG. 55 and FIGS. 56-68, another embodiment is described. Specifically, a method 4000 for forming an insulation feature 119 with a FinFET device 100 is described.

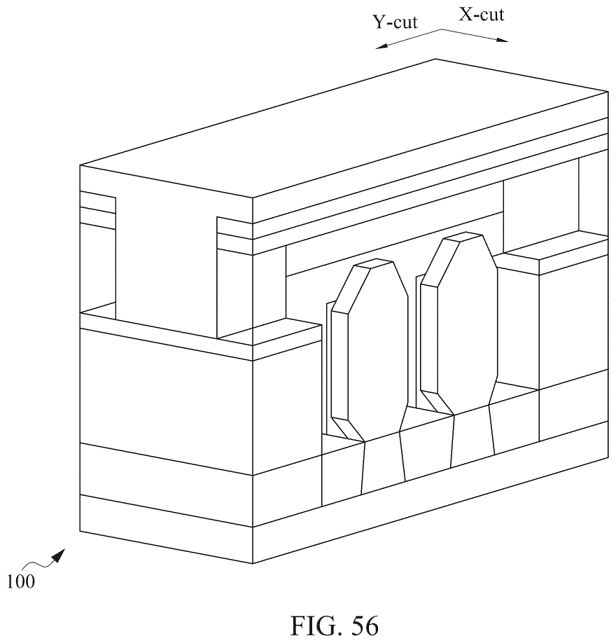

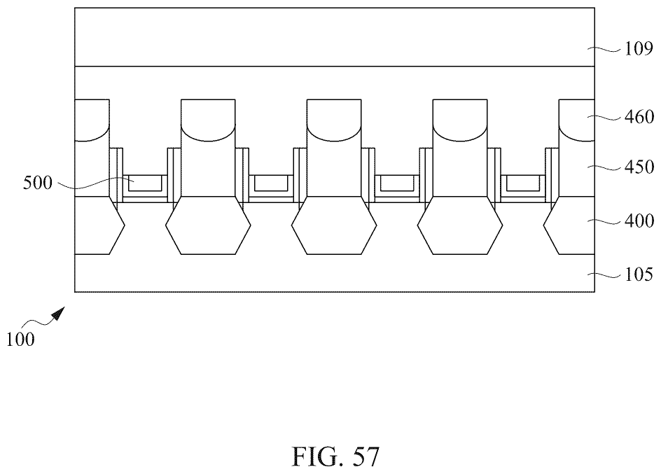

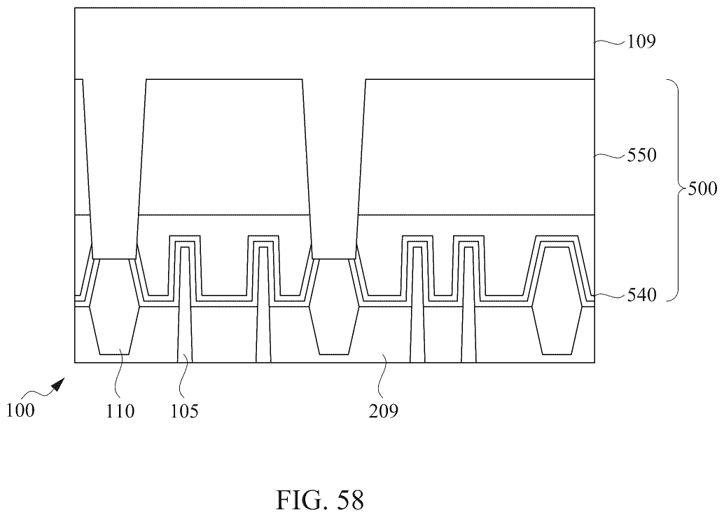

Cross-referencing FIG. 55 with FIGS. 56-58, method 3000 includes providing a device 100 with the FinFET structure at operation S4005. FIG. 56 provides a perspective view, FIG. 57 provides an X-cut cross-sectional view, and FIG. 58 provides a Y-cut cross-sectional view of a stage of fabrication.

As shown, in the device 100, fins 105 are formed from and over a substrate; and STI features 209 are formed around the fins 105. Also, dummy fins 110 are formed over the STI features 209. Source/drain features 400 are formed in the fins 105 around parallel sacrificial gates and a hard mask 460 is formed over the source/drain features 209. After the sacrificial gates are removed, parallel gates 500 are formed over the fins 105 and dummy fins 110. The gates 500 may include layers such as a work function metal and an amorphous silicon layer. As shown, gate dielectric 540 may be formed over the fins 105, dummy fins 110, and STI features 209 before the gates 500 are formed. As further shown, a mask 109, such as silicon nitride hard mask is formed over the structure of the device 100. In FIG. 58, the gate 500 is etched such that portions of the hard mask 109 extends downward to contact dummy fins 110 formed in the device 100 to define a region for removal.

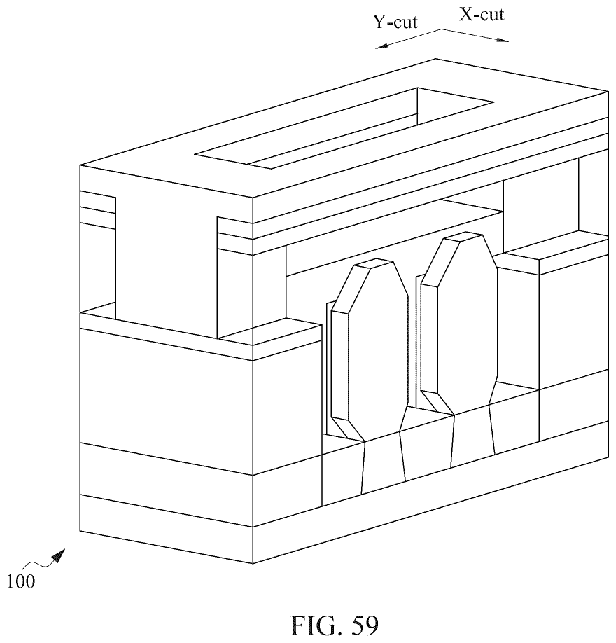

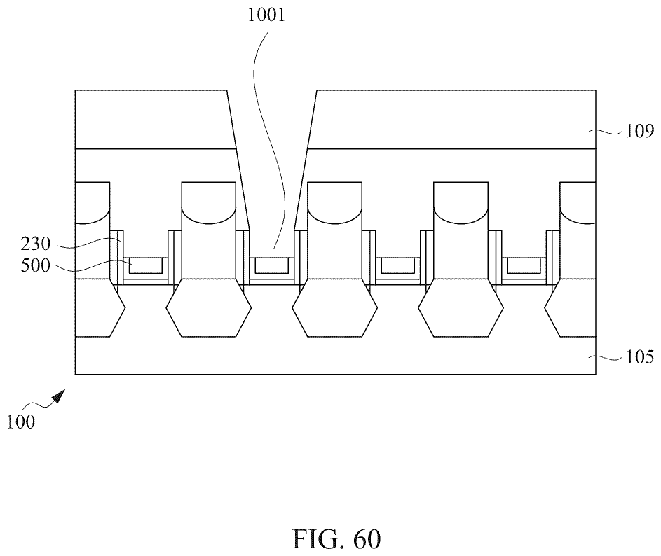

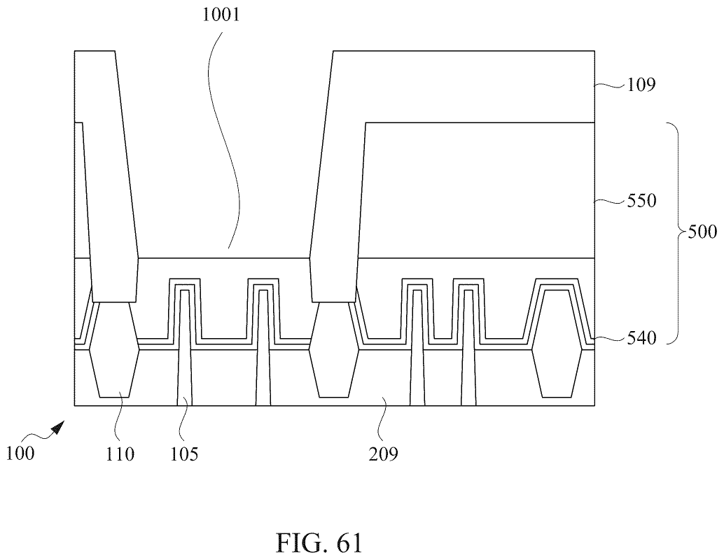

Cross-referencing FIG. 55 with FIGS. 59-61, method 3000 includes etching through the amorphous silicon layer to form opening 1001 over the fins 105 selected for removal at operation S4015. In certain embodiments, a dry etch is performed to remove the amorphous silicon layer. FIG. 59 provides a perspective view, FIG. 60 provides an X-cut cross-sectional view, and FIG. 61 provides a Y-cut cross-sectional view of a stage of fabrication.

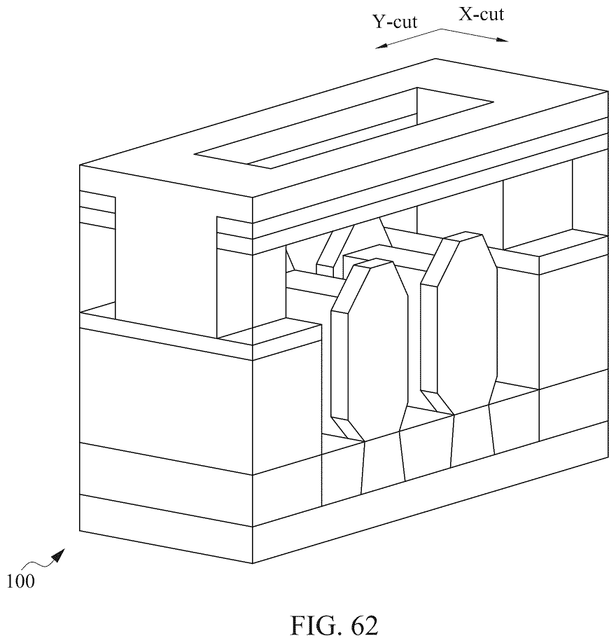

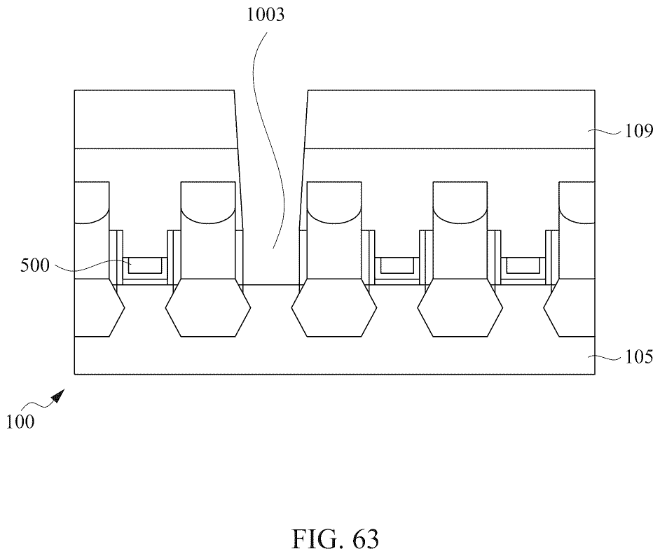

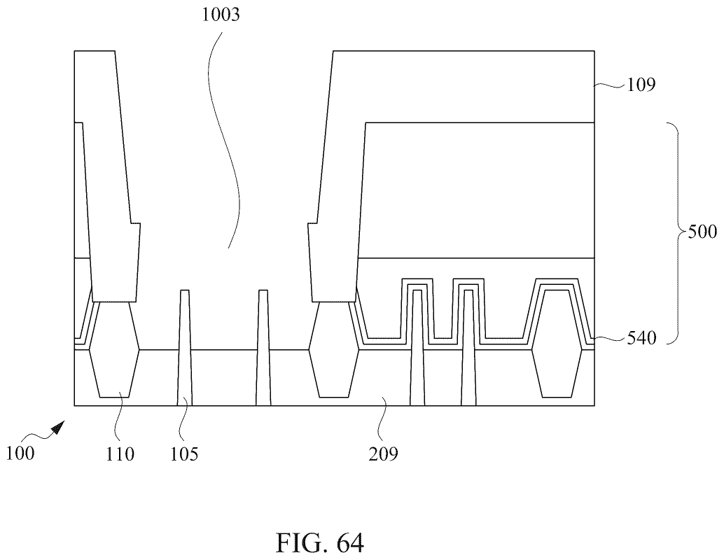

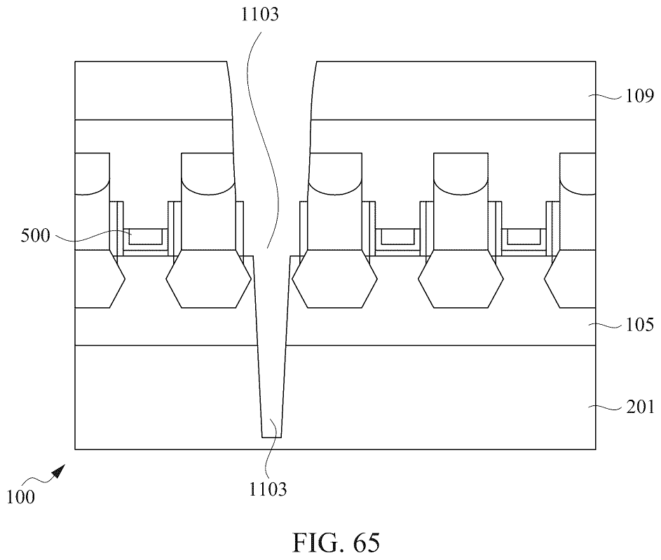

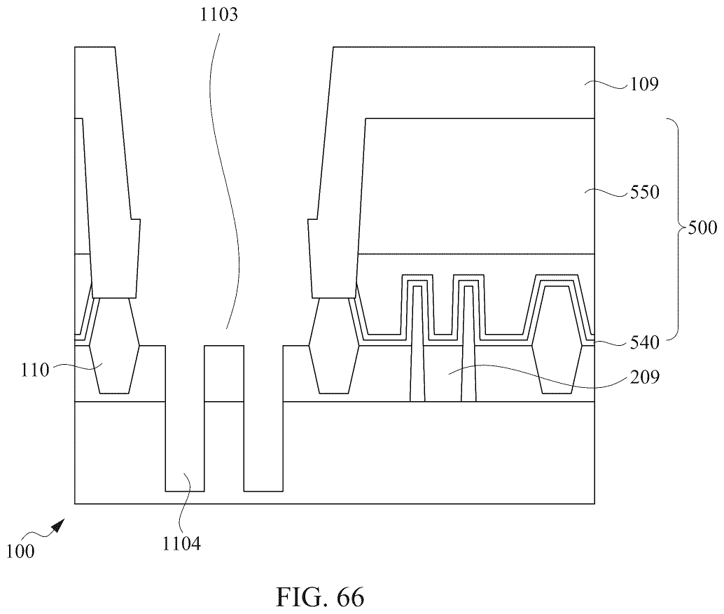

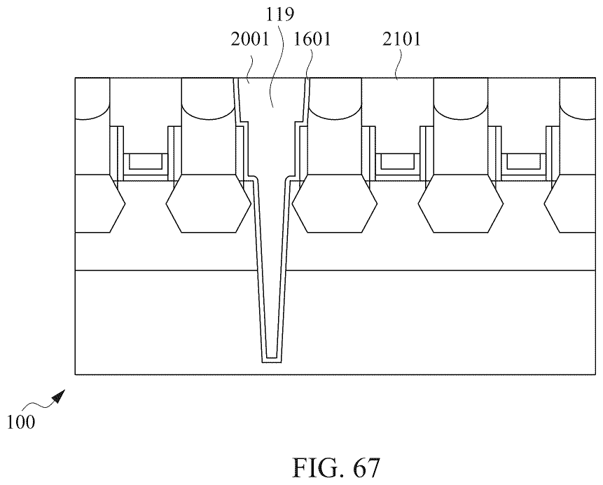

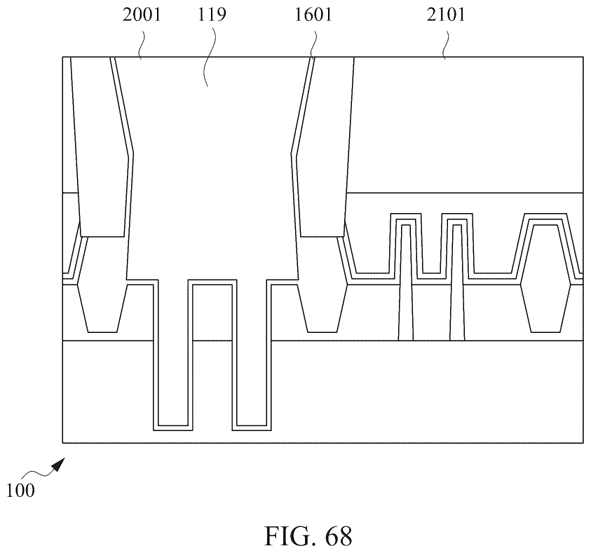

Cross-referencing FIG. 55 with FIGS. 62-64, method 3000 includes etching through the work function metal of gate 500 to remove the gate 500 and form opening 1003 over the fins 105 selected for removal at operation S4025. In certain embodiments, a wet etch or dry etch is performed to remove the work function metal of gate 500. FIG. 62 provides a perspective view, FIG. 63 provides an X-cut cross-sectional view, and FIG. 64 provides a Y-cut cross-sectional view of a stage of fabrication.

Cross-referencing FIG. 55, FIG. 65, an X-cut cross-sectional view, and FIG. 66, a Y-cut cross-sectional view of a stage of fabrication, method 3000 may continue, at operation S4035, with etching the sidewall spacers 230 and recessing the selected fins 105 to form cavity or opening 1103. As shown in FIG. 65, the sidewall spacers 230 may be completely removed when forming the opening 1103. As shown, the opening 1103 includes projections or fin cavities 1104 that extend through the STI region 209 and into the substrate 201.

In certain embodiments, the sidewall spacers 230 are removed by using oxide removal processes and/or by using low-k oxide selective sheet cut processes.

Cross-referencing FIG. 55, FIG. 67, an X-cut cross-sectional view, and FIG. 68, a Y-cut cross-sectional view of a stage of fabrication, method 3000 may continue, at operation S4045, with forming an insulation feature 119 in the opening 1103.

As shown, the insulation feature 119 may be formed by depositing a first insulating dielectric material 1601 in the opening 1103. The first insulating dielectric material 1601 may be formed as a liner that completely covers the surfaces of the openings 1103, and over the top surface of the dielectric material 109.

In certain embodiments, the first insulating dielectric material 1601 may include silicon oxide, oxynitride, a dielectric material having a dielectric constant (k) lower than silicon oxide (therefore referred to as low-k dielectric material layer), and/or other suitable dielectric material layer. In certain embodiments, the first insulating dielectric material 1601 is low-k silicon oxide.

Further, the insulation feature 119 may be formed by depositing a second insulating material 2001 over the first insulating material 1601. The second insulating material 2001 may completely fill the opening 1103.

In certain embodiments, the second insulating dielectric material 2001 may include silicon nitride, oxynitride, and/or other suitable dielectric material layer. In certain embodiments, the second insulating dielectric material 2001 is silicon nitride.

In certain embodiments, the second insulating dielectric material 2001 may be deposited with a refill process. In one example, the dielectric material 2001 may be deposited by chemical vapor deposition (CVD), atomic layer deposition (ALD), spin-on coating, or other suitable techniques. As shown, the second insulating dielectric material 2001 may be first formed as a blanket layer covering the surface of the dielectric material 109.

Operation S4045 further includes planarizing the structure of device 100 to form the insulation feature 119 in the opening 1103.

As shown, the planarization process may remove all of the overburden portions of the dielectric material 109, the first insulating material 1601, and the second insulating dielectric material 2001 and form the structure of device 100 with an upper surface 2101.

Operation S4045 may be considered to complete the insulation feature fabrication process by forming the insulation feature 119 including first insulating dielectric material 1601 and second insulating dielectric material 2001.

As shown in FIG. 55, method 4000 may include further processing at operation S4055. For example, various lithography, patterning, and passivation processes may be performed to form dielectric and metallization layers and to form a desired interconnect structure, such as in typical Back-end-of-line (BEOL) processing.

In an embodiment, a method is provided and includes forming fins over a substrate; forming a gate over the fins, wherein a sidewall spacer is laterally adjacent to the gate; removing an upper portion of the sidewall spacer; forming a cavity by removing a selected segment of the gate and removing a selected fin located under the selected segment; and forming an insulation feature in the cavity.

In certain embodiments of the method, an interlayer dielectric (ILD) structure is adjacent to the insulation feature, and the method further includes etching the ILD structure and forming a conductive interconnect to a source/drain feature adjacent to the insulation feature.

In certain embodiments, the method further includes forming a source/drain feature adjacent to the gate; forming an interlayer dielectric (ILD) structure over the source/drain feature, wherein the ILD structure and the sidewall spacer are formed from a same material; and etching the ILD structure and forming a conductive interconnect to the source/drain feature adjacent to the insulation feature, wherein, if the sidewall spacer is present when etching the ILD structure, the insulation feature covers the sidewall spacer to avoid etching of the sidewall spacer.

In certain embodiments of the method, removing the upper portion of the sidewall spacer includes removing all of the sidewall spacer.

In certain embodiments of the method, removing the upper portion of the sidewall spacer is performed after removing the selected segment of the gate.

In certain embodiments of the method, wherein the sidewall spacer includes low-k silicon oxide.

In certain embodiments of the method, wherein the gate is a metal gate.

In certain embodiments of the method, the gate is a sacrificial gate and the method further includes removing a remaining portion of the sacrificial gate to form a gate cavity; and forming a metal gate in the gate cavity.

In another embodiment, a method for fabricating a semiconductor device is provided and includes forming a fin over a substrate; forming a gate over the fin; forming source/drain features in the fin adjacent to the gate; forming interlayer dielectric (ILD) structures over the source/drain features, wherein the ILD structures include silicon oxide; removing a region including a portion of the fin and a portion of the gate to form an opening; forming an insulation feature in the opening; and performing a process to etch a selected ILD structure to an underlying source/drain feature, wherein, during the process, an exposed surface of the semiconductor device at and adjacent to the insulation feature is free of silicon oxide.

In certain embodiments, the method further includes forming a sidewall spacer, wherein the sidewall spacer is directly adjacent to the gate; and while removing the region including the portion of the fin and the portion of the gate to form the opening, removing at least an upper portion of a portion of the sidewall spacer within the region.

In certain embodiments, the method includes removing all of the sidewall spacer within the region.

In certain embodiments of the method, the process to etch the selected ILD structure does not etch an interface of the insulation feature.

In certain embodiments the method, the gate is a metal gate.

In certain embodiments the method, the gate is a sacrificial gate, and the method further includes after forming the insulation feature in the opening, removing a remaining portion of the sacrificial gate to form a gate cavity; and forming a metal gate in the gate cavity before performing the process to etch the selected ILD structure.

In another embodiment, a semiconductor device is provided and includes a fin 105 located over a substrate 201; source/drain features 400 located in recesses formed in the fin 105; an insulation feature 119 located between the source/drain features and extending through the fin and into the substrate, wherein the insulation feature has an uppermost surface, and wherein at the uppermost surface the insulation feature contacts a non-oxide dielectric layer.

In certain embodiments of the semiconductor device, a gate 500 is located over the fin, and wherein the insulation feature extends through the gate.

In certain embodiments of the semiconductor device, an oxide layer contacts a lower portion of the insulation feature, and wherein an upper portion of the insulation features is located above the oxide layer.

In certain embodiments of the semiconductor device, no portion of the insulation feature contacts an oxide layer.

In certain embodiments of the semiconductor device, a conductive interconnect is located above a selected source/drain feature, and a non-oxide dielectric layer contacts the conductive interconnect and the insulation feature.

In various embodiments, the insulation feature includes a liner formed from a first insulation dielectric material. In certain embodiments, the first insulation material is not silicon oxide and the insulation feature is free of silicon oxide. However, in certain embodiments, the first insulation material may be silicon oxide. In such embodiments, the liner formed from the first insulation material may have a small thickness, such as a thickness of no more than 4 nanometers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming fins over a substrate;
forming a gate over the fins, wherein a sidewall spacer is laterally adjacent to the gate;
removing an upper portion of the sidewall spacer;
forming a cavity by removing a selected segment of the gate and removing a selected fin located under the selected segment; and
forming an insulation feature in the cavity.

2. The method of claim 1, wherein an interlayer dielectric (ILD) structure is adjacent to the insulation feature, and wherein the method further comprises etching the ILD structure and forming a conductive interconnect to a source/drain feature adjacent to the insulation feature.

3. The method of claim 1, further comprising:
forming a source/drain feature adjacent to the gate;
forming an interlayer dielectric (ILD) structure over the source/drain feature, wherein the ILD structure and the sidewall spacer are formed from a same material;
etching the ILD structure and forming a conductive interconnect to the source/drain feature adjacent to the insulation feature,
wherein, if the sidewall spacer is present when etching the ILD structure, the insulation feature covers the sidewall spacer to avoid etching of the sidewall spacer.

4. The method of claim 1, wherein removing the upper portion of the sidewall spacer comprises removing all of the sidewall spacer.

5. The method of claim 1, wherein removing the upper portion of the sidewall spacer is performed after removing the selected segment of the gate.

6. The method of claim 1, wherein the sidewall spacer comprises low-k silicon oxide.

7. The method of claim 1, wherein the gate is a metal gate.

8. The method of claim 1, wherein the gate is a sacrificial gate and the method further comprises:
removing a remaining portion of the sacrificial gate to form a gate cavity; and
forming a metal gate in the gate cavity.

9. A method for fabricating a semiconductor device, the method comprising:
forming a fin over a substrate;
forming a gate over the fin;
forming source/drain features in the fin adjacent to the gate;
forming interlayer dielectric (ILD) structures over the source/drain features, wherein the ILD structures comprise silicon oxide;
removing a region including a portion of the fin and a portion of the gate to form an opening;
forming an insulation feature in the opening; and
performing a process to etch a selected ILD structure to an underlying source/drain feature, wherein, during the process, an exposed surface of the semiconductor device at and adjacent to the insulation feature is free of silicon oxide.

10. The method of claim 9, further comprising:
forming a sidewall spacer, wherein the sidewall spacer is directly adjacent to the gate; and
while removing the region including the portion of the fin and the portion of the gate to form the opening, removing at least an upper portion of a portion of the sidewall spacer within the region.

11. The method of claim 10, comprising removing all of the sidewall spacer within the region.

12. The method of claim 9, wherein the process to etch the selected ILD structure does not etch an interface of the insulation feature.

13. The method of claim 9, wherein the gate is a metal gate.

14. The method of claim 9, wherein the gate is a sacrificial gate.

15. The method of claim 9, wherein the gate is a sacrificial gate, and wherein the method further comprises:
after forming the insulation feature in the opening, removing a remaining portion of the sacrificial gate to form a gate cavity; and
forming a metal gate in the gate cavity before performing the process to etch the selected ILD structure.

16. A semiconductor device comprising:
a fin located over a substrate;
source/drain features located in recesses formed in the fin;
an insulation feature located between the source/drain features and extending through the fin and into the substrate, wherein the insulation feature has an uppermost surface, and wherein at the uppermost surface the insulation feature contacts a non-oxide dielectric layer.

17. The semiconductor device of claim 16, wherein a gate is located over the fin, and wherein the insulation feature extends through the gate.

18. The semiconductor device of claim 16, wherein an oxide layer contacts a lower portion of the insulation feature, and wherein an upper portion of the insulation feature is located above the oxide layer.

19. The semiconductor device of claim 16, wherein no portion of the insulation feature contacts an oxide layer.

20. The semiconductor device of claim 16, wherein a conductive interconnect is located above a selected source/drain feature, and wherein a non-oxide dielectric layer contacts the conductive interconnect and the insulation feature.
